(19) United States
(12) Patent Application Publication
(10) Pub. No.: US 2024/0420794 A1
(43) Pub. Date: Dec. 19, 2024

(54) NON-VOLATILE MEMORY

(71) Applicant: SAMSUNG ELECTRONICS CO., LTD., Suwon-si (KR)

(72) Inventors: Youhwan Kim, Suwon-si (KR); Sewoong Lee, Suwon-si (KR); Haedong No, Suwon-si (KR); Ho-Sung Ahn, Suwon-si (KR); Youn-Soo Cheon, Suwon-si (KR)

(21) Appl. No.: 18/624,904

(22) Filed: Apr. 2, 2024

(30) Foreign Application Priority Data
Jun. 13, 2023 (KR) 10-2023-0075710

(51) Int. Cl. G11C 29/52; G11C 16/08; G11C 29/50

(52) U.S. Cl. CPC G11C 29/52; G11C 16/08; G11C 29/50016

(57) ABSTRACT

A non-volatile memory device comprises a memory cell array comprising a plurality of memory cell blocks; and an address decoder connected to the memory cell array through a plurality of word lines and configured to apply a read pass voltage to unselected word lines of a selected memory cell block among the plurality of memory cell blocks and apply the read pass voltages of different levels to different memory cell blocks among the plurality of memory cell blocks.

### CROSS-REFERENCE TO RELATED APPLICATION

This application claims priority to and the benefit of Korean Patent Application No. 10-2023-0075710 filed in the Korean Intellectual Property Office on Jun. 13, 2023, the entire content of which is incorporated herein by reference.

### BACKGROUND

A memory device may be used to store data, and can be categorized to a volatile memory device and a non-volatile memory device. Non-volatile memory devices can store data even when power is cut off. Non-volatile memory devices are mainly used as large-capacity memories for storing programs and data in a wide range of application devices such as computers and portable communication devices.

As non-volatile memory devices have recently increased in density and capacity, various problems have occurred.

### SUMMARY

In general, in some aspects, the subject matter of the present disclosure encompasses a non-volatile memory device, a storage device, and a method of operating the storage device preventing read disturb deterioration.

In general, in some aspects, the subject matter of the present disclosure encompasses a non-volatile memory device, a storage device, and a method of operating the storage device preventing occurrence of an uncorrectable error correction code (UECC).

According to some aspects of the present disclosure, a non-volatile memory device comprises a memory cell array comprising a plurality of memory cell blocks; and an address decoder connected to the memory cell array through a plurality of word lines and configured to apply a read pass voltage to unselected word lines of a selected memory cell block among the plurality of memory cell blocks and apply the read pass voltages of different levels to different memory cell blocks among the plurality of memory cell blocks.

According to some aspects of the present disclosure, a storage device comprises a non-volatile memory device comprising a memory cell block; and a storage controller configured to check a retention level of the memory cell block and control the non-volatile memory device to apply a read pass voltage determined based on the retention level to the memory cell block.

According to some aspects of the present disclosure, an operating method of a storage device comprises checking a retention level of a memory cell block included in a non-volatile memory device; determining a level of a read pass voltage applied to the memory cell block based on the retention level; and transmitting a command for controlling the level of the read pass voltage to the determined level to the non-volatile memory device.

### BRIEF DESCRIPTION OF THE DRAWINGS

The above and other aspects and features will be more apparent from the following description of implementations with reference to the attached drawings, in which:

FIG. 1 is a block diagram of a storage device and a memory system including the same according to some implementations.

FIG. 2 is a flowchart of an operation method of a storage device according to some implementations.

FIG. 3 is a block diagram of a non-volatile memory device according to some implementations.

FIG. 4 is a perspective view of a memory cell block included in a memory cell array of a non-volatile memory device of FIG. 3.

FIG. 5 shows cell strings included in a memory cell block and voltages applied to the cell strings according to some implementations.

FIG. 6 is a block diagram of a storage controller according to some implementations.

FIG. 7 is a block diagram of a control circuit of a non-volatile memory device according to some implementations.

FIG. 8 is a block diagram of a voltage generator of a non-volatile memory device according to some implementations.

FIG. 9 is a block diagram of a voltage generator, an address decoder, and a memory cell block of a non-volatile memory device according to some implementations.

FIG. 10 is flowchart of an operation method of a storage device according to some implementations.

FIG. 11 is a distribution diagram illustrating off-cell count operation of the non-volatile memory device according to some implementations.

FIG. 12 is a table of offset values of a read pass voltage corresponding to off-cell count values according to some implementations.

FIG. 13 is a timing diagram of voltages applied to cell strings of FIG. 5 according to an operation method of a storage device according to some implementations.

FIG. 14 is a flowchart illustrating an operation method of a storage device according to some implementations.

FIG. 15 is a flowchart illustrating an operation method of a storage device according to some implementations.

FIG. 16 is a flowchart illustrating an operation method of a storage device according to some implementations.

FIG. 17 is a flowchart illustrating an operation method of a storage device according to some implementations.

FIG. 18 is a perspective view illustrating a semiconductor device according to some implementations.

FIG. 19 is a cross-sectional view illustrating an example of a semiconductor device according to some implementations.

FIG. 20 shows cell strings included in a memory cell block and voltages applied to the cell strings according to some implementations.

FIG. 21 is a flowchart illustrating an operation method of a storage device according to some implementations.

FIG. 22 is a flowchart illustrating an operation method of a storage device according to some implementations.

FIG. 23 is a flowchart illustrating an operation method of a storage device according to some implementations.

FIG. 24 is a graph illustrating the number of error bits per 4 KB according to the number of page reads for each read pass voltage according to some implementations.

FIG. 25 is a graph illustrating threshold voltage distribution for each read pass voltage according to some implementations.

FIG. 26 is a graph illustrating the number of executions of defense codes for each read pass voltage according to some implementations.

FIG. 27 is a block diagram illustrating an example of a solid-state drive (SSD) system applied a non-volatile memory device according to some implementations.

### DETAILED DESCRIPTION

Example implementations will be described more fully hereinafter with reference to the accompanying drawings. Each implementation provided in the following description is not excluded from being associated with one or more features of another example or another implementation also provided herein or not provided herein but consistent with the present disclosure. In the following detailed description, only certain implementations of the present invention have been shown and described, simply by way of illustration. As those skilled in the art would realize, the described implementations may be modified in various different ways, all without departing from the spirit or scope of the present invention.

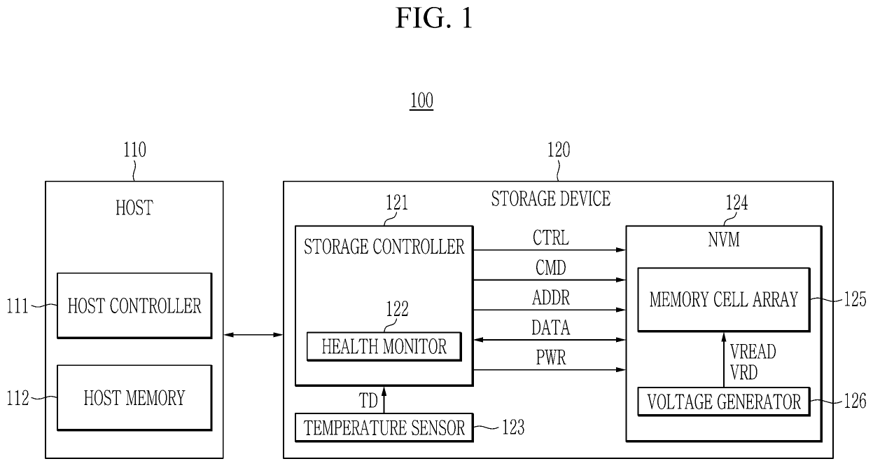

FIG. 1 is a block diagram of a storage device and a memory system including the same according to some implementations.

Referring to FIG. 1, a storage system 100 may include a host device 110 and a storage device 120. In some implementations, the storage system 100 is a mobile phone, a smart phone, a tablet personal computer (PC), a wearable device, and a mobile system, such as a healthcare device, or an Internet of Things (IOT) device. In some implementations, the storage system 100 is a computing device such as a personal computer, a laptop computer, a server, or a media player, or a system a such as an automotive device (e.g., a navigation device).

The host device 110 may store data in the storage device 120 or read data stored in the storage device 120. The host device 110 may include a host controller 111 and a host memory 112. The host controller 111 may be configured to control the storage device 120. The host controller 110 may have an operating system (OS) installed therein, and may control overall internal operations of the host device 110 by the operating system (OS). The operating system (OS) may be, for example, any one of Windows series, Unix series, and Linux series. In some implementations, the host controller 111 may communicate with the storage device 120 based on a predetermined interface. For example, these interfaces can be implemented with various interfaces such as advanced technology attachment (ATA), serial ATA (SATA), external SATA (e-SATA), small computer small interface (SCSI), serial attached SCSI (SAS), peripheral component interconnection (PCI), Various interfaces such as PCI express (PCI-E), IEEE 1394, universal serial bus (USB), secure digital (SD) card, multi media card (MMC), embedded multi media card (eMMC), compact flash (CF) card, etc.

The host memory 112 may be a buffer memory, working memory, or system memory of the host device 110. For example, the host memory 112 may be configured to store various information necessary for the host device 110 to operate. The host memory 112 may be used as a buffer memory or a working memory for temporarily storing data to be transmitted to the storage device 120 or data received from the storage device 120. For example, the host memory 120 may be implemented with a volatile memory such as dynamic random-access memory (DRAM) or static random-access memory (SRAM) or a non-volatile memory such as phase change random-access memory (PRAM) or flash memory. Host memory 112 may support access by storage device 120.

According to some implementations, the host controller 110 and the host memory 120 may be implemented as separate semiconductor chips. Alternatively, in some implementations, the host controller 110 and the host memory 120 may be integrated on the same semiconductor chip. As an example, the host controller 110 may be any one of a plurality of modules included in an application processor, and the application processor may be implemented as a system on chip (SoC). Also, the host memory 120 may be an embedded memory included in the application processor, or may be a non-volatile memory or a memory module disposed outside the application processor.

The storage device 120 may be a storage medium configured to store data or output stored data according to a request from the host device 110. As an example, the storage device 120 may include at least one of a solid state drive (SSD), an embedded memory, and a removable external memory. When the storage device 120 is an SSD, the storage device 120 may be a device conforming to standards such as non-volatile memory express (NVMe), SATA, and SAS. When the storage device 120 is an embedded memory or an external memory, the storage device 120 may be a device conforming to a standard such as universal flash storage (UFS), embedded multi-media card (eMMC), or security digital (SD), and the protocol is not limited thereto. The host device 110 and the storage device 120 may respectively generate and transmit packets according to adopted standard protocols.

The storage device 120 may include a storage controller 121 and a non-volatile memory device 124. In addition, the storage device 120 may further include a temperature sensor 123.

The storage controller 121 may store data DATA in the non-volatile memory device 124 or read data DATA stored in the non-volatile memory device 124. For example, the storage controller 121 may store data DATA in the non-volatile memory device 124 or read data DATA stored in the non-volatile memory device 124 by transmitting the control signal CTRL, the command CMD, and the address ADDR to the non-volatile memory device 124.

In some implementations, the storage controller 121 may check the retention level of the non-volatile memory device 124. For example, the storage controller 121 may perform an off-cell count operation on the non-volatile memory device 124 and check the retention level based on the off-cell count value. The storage controller 121 may check the retention level based on the time that has elapsed since the program operation was performed. The storage controller 121 may check the retention level based on the number of errors generated in the non-volatile memory device 124. The off-cell count operation may be performed when the storage device 120 is in an IDLE state so as not to affect the performance of the host device 110.

In some implementations, the storage controller 121 may control the non-volatile memory device 124 to change the level of the read pass voltage VREAD based on the retention level. The storage controller 121 may control the non-volatile memory device 124 to change the level of the read pass voltage VREAD to a relatively small level, when the retention level is high, that is, when retention deterioration has occurred relatively less. The storage controller 121 may control the non-volatile memory device 124 to change the level of the read pass voltage VREAD, when the retention level is low, that is, when the retention deterioration has occurred relatively high. In some implementations, the storage controller 121 may include a health monitor 122 that checks the retention level of the non-volatile memory device 124. The storage controller 121 may generate a command CMD for controlling the level of the read pass voltage VREAD based on the checked retention level.

In some implementations, the storage controller 121 may check the retention level of the non-volatile memory device 124 by referring to the temperature information TD provided from the temperature sensor 123. For example, the storage controller 121 may check the retention level of the non-volatile memory device 124 when a period determined based on the temperature information TD elapses. The temperature sensor 123 may measure the internal temperature of the non-volatile memory device 124 and generate a driving temperature TD converted into numerical information. For example, the temperature sensor 123 may be a thermal electromotive force (or thermocouple) sensor that uses electromotive force that varies with temperature, a thermal conductivity type sensor that detects a magnitude of resistance that varies with temperature, and the like. However, it will be well understood that the temperature measuring method of the temperature sensor 123 is not limited thereto and may be applied in various ways.

The non-volatile memory device 124 may perform an erase, write, or read operation under the control of the storage controller 121. For this purpose, the non-volatile memory device 124, through the input and output lines, receives a command CMD and an address ADDR from the storage controller 121 and transmits and receives data DATA for a program operation or a read operation with the storage controller 121. Also, the non-volatile memory device 124 may receive a control signal CTRL through a control line, and the non-volatile memory device 124 may receive power PWR from the storage controller 121.

The non-volatile memory device 124 may include a memory cell array 125 and a voltage generator 126. The memory cell array 125 may include a plurality of memory cells, for example, the plurality of memory cells may be flash memory cells. The flash memory may include a 2D NAND memory array or a 3D (or vertical) NAND (VNAND) memory array. Hereinafter, some implementations of the present disclosure will be described taking a case in which a plurality of memory cells are NAND flash memory cells as an example. However, the technical idea of the present disclosure is not limited thereto, and the plurality of memory cells may be various types of non-volatile memory cells. In some implementations, the plurality of memory cells may be resistive memory cells such as resistive RAM (RRAM), PRAM, or magnetic RAM (MRAM).

The memory cell array 125 may include a plurality of memory cell blocks. Each of the memory cell blocks may include a plurality of cell strings sharing a bit line. Each of the plurality of cell strings may include a ground selection transistor, a plurality of memory cells connected to a plurality of word lines, and a string selection transistor. The memory cell array 125 may be a two-dimensional (2D) memory array. Alternatively, the memory cell array 125 may be a three-dimensional (3D) memory array.

The voltage generator 126 may generate a voltage applied to the memory cell array 125. For example, the voltage generator 126 may generate a read voltage VRD provided to a selected word line and a read pass voltage VREAD provided to a non-selected word line in a read operation.

In some implementations, the voltage generator 126 may change the size of the read pass voltage VREAD based on the retention level of the memory cell array 125. For example, the voltage generator 126 may receive a command CMD to change a voltage level of the read pass voltage VREAD to a voltage level determined based on the retention level from the storage controller 121, and may change the voltage level of the read pass voltage VREAD.

In some implementations, the voltage generator 126 may generate different levels of the read pass voltage VREAD for each memory cell block. The voltage generator 126 may generate different levels of the read pass voltage VREAD for each word line.

According to some implementations, as a read pass voltage (VREAD) provided to a memory cell block or word line having a relatively low retention level is greater than a read pass voltage (VREAD) provided to a memory cell block or word line having a relatively high retention level, read disturb deterioration due to a read pass voltage (VREAD) of a memory cell block or a memory cell connected to a word line having a relatively high retention level is prevented, and a read error of a memory cell block having a relatively low retention level or a memory cell connected to a word line may be prevented.

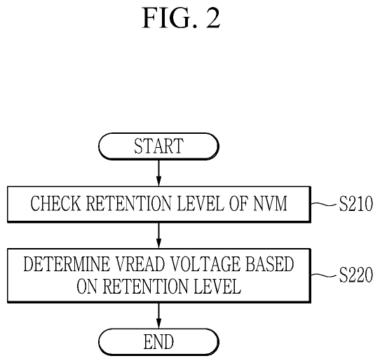

FIG. 2 is a flowchart of an operation method of a storage device according to some implementations.

Referring to FIGS. 1 and 2 together, the storage controller 121 checks the retention level of the non-volatile memory device 122 (S210). For example, the storage controller 121 may perform an off-cell count operation on the non-volatile memory device 124 and check the retention level based on the off-cell count value. The storage controller 121 may check the retention level based on the time that has elapsed since the program operation was performed. For example, the storage controller 121 may decrease the retention level in response to an elapsed time after performing the program operation. The storage controller 121 may check the retention level based on the number of read errors generated in the non-volatile memory device 124. For example, the storage controller 121 may check a retention level corresponding to a range including the number of read errors generated in the non-volatile memory device 124. The storage controller 121 may determine that the non-volatile memory device 124 having a relatively greater number of read errors has a relatively lower retention level. The storage controller 121 may determine that the non-volatile memory device 124 where UECC has occurred has a relatively lower retention level. The storage controller 121 may check the retention level based on the number of UECCs generated in the non-volatile memory device 124. For example, the storage controller 121 may check a retention level corresponding to a range including the number of UECCs generated in the non-volatile memory device 124.

The storage controller 121 may check the retention level of each of a plurality of memory cell blocks included in the non-volatile memory device 124. The storage controller 121 may check the retention level of a memory cell for each word line included in each of a plurality of memory cell blocks.

In some implementations, the storage controller 121 may check the retention level of the non-volatile memory device 124 by referring to the temperature information TD provided from the temperature sensor 123. For example, the storage controller 121 may check the retention level of the non-volatile memory device 124 when a period determined based on the temperature information TD elapses.

The storage controller 121 determines the read pass voltage VREAD based on the retention level (S220). The storage controller 121 may determine the read pass voltage VREAD to have a higher voltage level as the retention level of the non-volatile memory device 124 is lower.

For example, the storage controller 121 may determine a higher level of the read pass voltage VREAD applied to the unselected word line during a read operation of the first memory cell block when the retention level of the first memory cell block is the second level lower than the first level than the level of the read pass voltage VREAD applied to the unselected word line during a read operation of the first memory cell block when the retention level of the first memory cell block included in the non-volatile memory device 124 is the first level. When the retention level of the first memory cell block included in the non-volatile memory device 124 is the first level and the retention level of the second memory cell block is the second level, the storage controller 121 may determine the level of the read pass voltage VREAD applied to the unselected word line during a read operation of the first memory cell block higher than the level of the second read pass voltage VREAD applied to the unselected word line during a read operation of the second memory cell block. In some implementations, the storage controller 121 may generate a command CMD that controls the voltage generator 126 to generate the read pass voltage VREAD at the determined level of the read pass voltage VREAD.

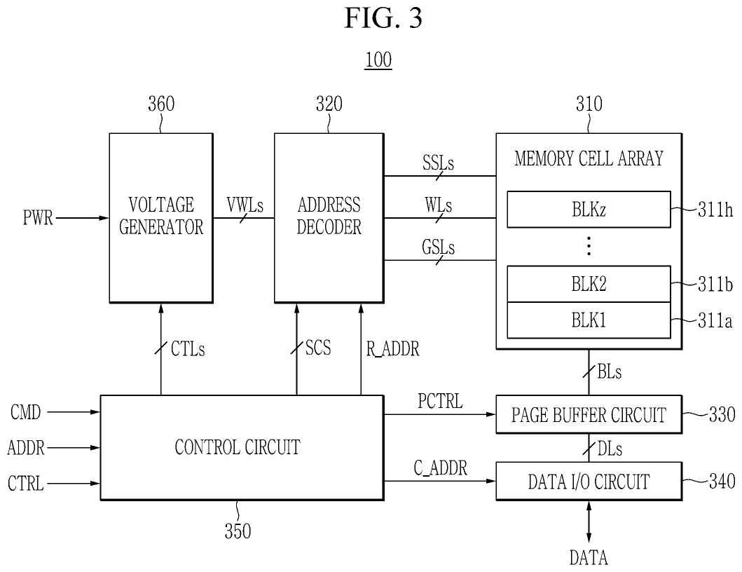

FIG. 3 is a block diagram of a non-volatile memory device according to some implementations.

Referring to FIG. 3, the non-volatile memory device 300 may include a memory cell array 310, an address decoder 320, a page buffer circuit 330, a data input/output circuit 340, a control circuit 350, and a voltage generator 360.

The memory cell array 310 may include a plurality of memory cell blocks 311a, 311b, . . . , 311h. Each of the memory cell blocks 311a, 311b, . . . , 311h may include a plurality of non-volatile memory cells. Each of the memory cell blocks 311a, 311b, . . . , 311h may be connected to the address decoder 320 through a plurality of string select lines (SSLs), a plurality of word lines (WLs), and a plurality of ground select lines (GSLs). Also, the memory cell array 310 may be connected to the page buffer circuit 330 through a plurality of bit lines BLs. The memory cell blocks 311a, 311b, . . . , 311h may be commonly connected to a plurality of bit lines BLs. A plurality of non-volatile memory cells included in the memory cell blocks 311a, 311b, 311h may have the same structure. In some implementations, the memory cell array 310 may be a 3D memory cell array formed in a three-dimensional structure (or vertical structure) on a substrate. In this case, the memory cell array 310 may include vertical cell strings including a plurality of memory cells stacked on each other.

The address decoder 320 may be connected to the memory cell array 310 through a plurality of string select lines SSLs, a plurality of word lines WLs, and a plurality of ground select lines GSLs.

During a program operation or a read operation, the address decoder 320 may determine one of a plurality of word lines WLs as a selected word line and the other word lines as unselected word lines based on the row address R_ADDR provided from the control circuit 350. The address decoder 320 determines one of the plurality of string selection lines SSLs as a selected string selection line, and remaining string selection lines as non-selection strings based on the switching control signal SCS provided from the control circuit 350. The address decoder 320 may adjust the floating timing of the ground selection lines GSLs according to the switching control signal SCS during an erase operation.

For example, during programming, the address decoder 320 may apply a program voltage to the selected word line of the selected memory cell block and apply a pass voltage to non-selected word lines of the selected memory cell block based on the row address R_ADDR. During reading, the address decoder 320 may apply a read voltage to the selected word line of the selected memory cell block and may apply a read pass voltage to non-selected word lines of the selected memory cell block based on the row address R_ADDR. During erase, the address decoder 320 may apply erase voltages (e.g., a ground voltage or low voltages having levels similar to the ground voltage) to word lines of the selected memory cell block.

In some implementations, the address decoder 320 may apply read pass voltages of different levels transferred from the voltage generator 360 to different memory cell blocks.

The address decoder 320 may apply a read pass voltage of a first level to un selected word lines in one memory cell block at a first time point, and apply a read pass voltage different from the first level to unselected word lines in the memory cell block at a second time point. In this case, the second time point is a time point after the first time point, and the second level may be greater than the first level. The address decoder 320 may apply read pass voltages of different levels transferred from the voltage generator 360 to different unselected word lines within the same memory cell block, respectively.

The page buffer circuit 330 may be connected to the memory cell array 310 through a plurality of bit lines BLs. The page buffer circuit 330 may include a plurality of page buffers. The page buffer circuit 330 may temporarily store data to be programmed in a selected page during a program operation, and may temporarily store data read from the selected page during a read operation.

The data input/output circuit 340 may be connected to the page buffer circuit 330 through a plurality of data lines DLs. During a program operation, the data input/output circuit 340 may receive program data DATA from the storage controller (121 of FIG. 1), and provide program data DATA to the page buffer circuit 330 based on the column address C_ADDR provided from the control circuit 350. During a read operation, the data input/output circuit 340 may provide the read data DATA stored in the page buffer circuit 330 to the storage controller 121 based on the column address C_ADDR provided from the control circuit 350.

The control circuit 350 may receive the command signal CMD and the address signal ADDR from the storage controller 121, and control an erase loop, a program loop, and a read operation of the non-volatile memory device 300 based on the command signal CMD and the address signal ADDR. Here, the program loop may include a program operation and a program verify operation, and the erase loop may include an erase operation and an erase verify operation. Here, the read operation may include a normal read operation and a data recovery read operation.

For example, the control circuit 350 may generate control signals (CTLs) for controlling the voltage generator 360, a page buffer control signal (PCTL) for controlling the page buffer circuit 330, and a control signal (VCS) for controlling the voltage detector 370, and generate a row address R_ADDR and a column address C_ADDR based on the address signal ADDR. The control circuit 350 may provide the row address R_ADDR to the address decoder 320 and the column address C_ADDR to the data input/output circuit 340. Also, the control circuit 350 may provide the switching control signal SCS to the address decoder 320 based on the command signal CMD.

The control circuit 350 may generate control signals CTLs and/or a switching control signal SCS based on the command signal CMD. In some implementations, the control circuit 350 may generate control signals CTLs that change the level of the read pass voltage generated by the voltage generator 360 based on the command signal CMD. The control circuit 350 may generate the switching control signal (SCS) so that the level-changed read pass voltage is applied to a corresponding memory cell block among the memory cell blocks 311a, 311b, . . . , 311h through the address decoder 320.

For example, to apply a read pass voltage of a first level to a first memory cell block among the memory cell blocks 311a, 311b, . . . , 311h, and apply a read pass voltage of a second level different from the first level to a second memory cell block among the memory cell blocks 311a, 311b, . . . , 311h, the control circuit 350 may generate control signals CTLs and/or a switching control signal SCS based on the command signal CMD, so that the voltage generator 360 generates read pass voltages of a first level and a second level, and the address decoder 320 applies a read pass voltage of a first level to the first memory cell block and a read pass voltage of a second level to the second memory cell block.

The voltage generator 360 may generate word line voltages VWLs, a string select line voltage, and a ground select line voltage necessary for the operation of the non-volatile memory device 300 using the power PWR based on the control signals CTLs provided from the control circuit 350,

The word line voltages VWLs generated by the voltage generator 360 may be applied to the plurality of word lines WLs through the address decoder 320. The string selection line voltage generated by the voltage generator 360 may be applied to the plurality of string selection lines SSLs through the address decoder 320. The ground select line voltage generated by the voltage generator 360 may be applied to the plurality of ground select lines GSLs through the address decoder 320.

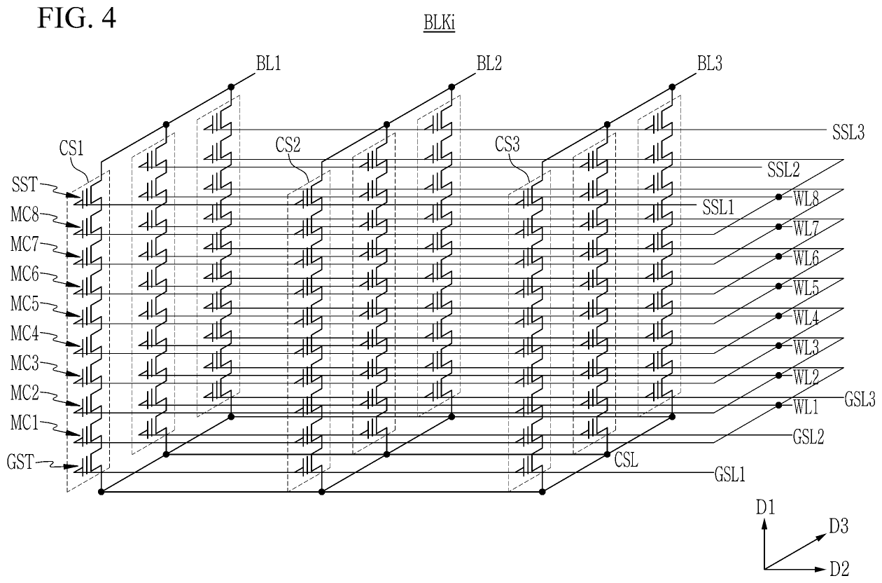

FIG. 4 is a perspective view of a memory cell block included in a memory cell array of a non-volatile memory device of FIG. 3.

Referring to FIG. 4, a cell array of a non-volatile memory device may include a plurality of memory cell blocks. The memory cell block BLKi may include cell strings CS1, CS2, and CS3 two-dimensionally arranged along second and third directions D2 and D3 crossing each other and extending along the first direction D1. Cell strings CS1, CS2, and CS3 may be connected to bit lines BL1, BL2, and BL3. The two-dimensionally arranged cell strings CS1, CS2, and CS3 may be commonly connected to the common source line CSL.

Each of the cell strings CS1, CS2, and CS3 may include a plurality of memory cells MC1, . . . , MC8 serially connected to each other in the first direction D1, a ground selection transistor GST connected in series between the common source line CSL and the plurality of memory cells MC1, . . . , MC8, and a string select transistor SST connected between the plurality of memory cells MC1, MC8 and corresponding bit lines among the bit lines BL1, BL2, and BL3. In FIG. 3, each of the cell strings CS1, CS2, and CS3 is illustrated as including eight memory cells MC1, . . . , MC8, but is not limited thereto.

The memory cells MC1, . . . , and MC8 may be respectively controlled by a plurality of word lines WL1, . . . , and WL8. Gate electrodes of the memory cells MC1, . . . , and MC8 positioned at the same level from the common source line CSL may be connected in common to one of the word lines WL1, . . . , and WL8. In addition, each of the memory cells MC1, . . . , MC8 may include a data storage element. The ground selection lines GSL1, GSL2, and GSL3 and the string selection lines SSL1, SSL2, and SSL3 may be separated from each other.

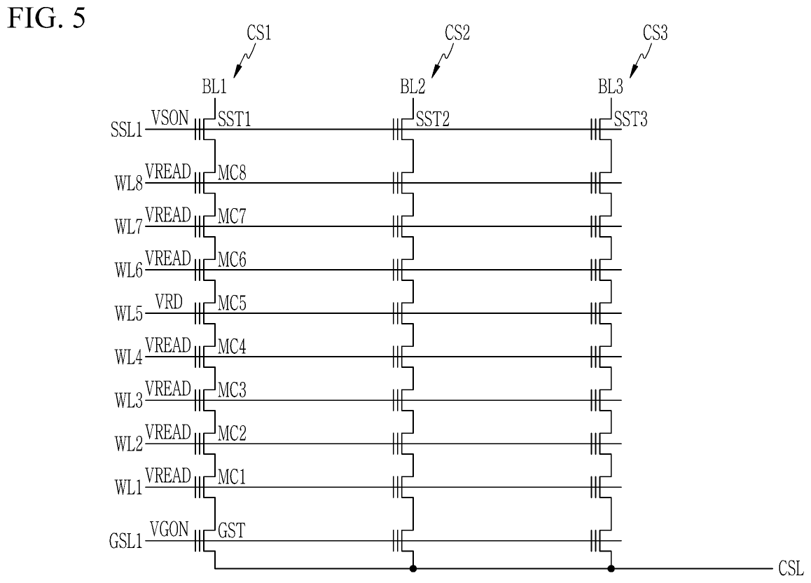

FIG. 5 shows cell strings included in a memory cell block and voltages applied to the cell strings according to some implementations.

Referring to FIG. 5, during read operation and/or program verification operation, the non-volatile memory device may read data stored in memory cells connected to the selected word line WL5 by applying the read voltage VRD to the selected word line WL5 connected to the selected cell strings CS1, CS2, and CS3.

Predetermined turn-on voltages VSON and VGON may be applied to the first string selection line SSL1, which is a selection string selection line, and the first ground selection line GSL1, which is a selection ground selection line, respectively. A read voltage VRD may be applied to the selected word line, the fifth word line WL5. The read pass voltage VREAD may be applied to the first to fourth and sixth to eighth word lines WL1, WL4, WL6, WL8, which are unselected word lines.

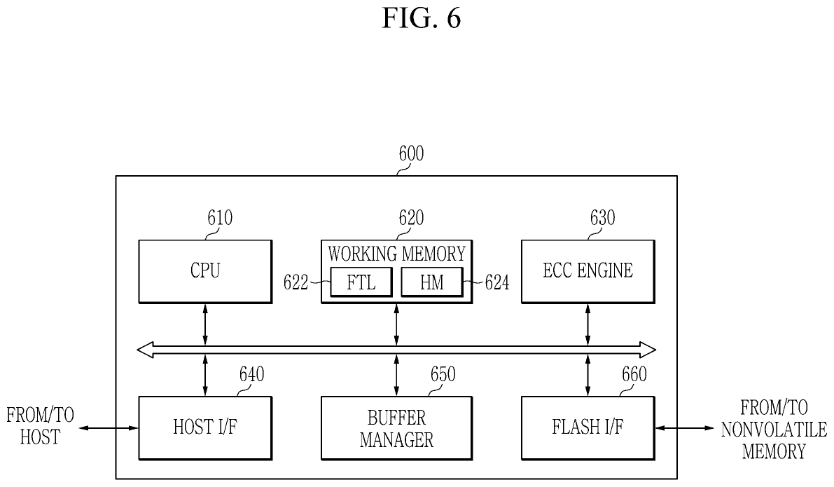

FIG. 6 is a block diagram of a storage controller according to some implementations.

Referring to FIG. 6, the storage controller 600 may include a central processing unit (CPU) 610, a working memory 620, an error correction code (ECC) engine 630, a host interface circuit. 640, a buffer memory 650, and a flash interface circuit 660.

The CPU 610 may control overall operations of the storage controller 600. The CPU 610 may control the operation of the storage controller 600 in response to a command received from the host device (110 in FIG. 1) through the host interface circuit 640. For example, the processor 610 may control each component by utilizing firmware for driving the storage device.

The working memory 620 may operate under the control of the CPU 610 and may be used as a working memory, a buffer memory, a cache memory, and the like. For example, the working memory 620 may be implemented with a volatile memory such as DRAM or SRAM or a non-volatile memory such as PRAM or flash memory.

A flash translation layer (FTL) 622 may be loaded into the working memory 620. When the CPU 610 executes the FTL 622, data writing and reading operations for the non-volatile memory device (124 in FIG. 1) may be controlled. The FTL 622 may perform various functions such as address mapping, wear-leveling, and garbage collection. The address mapping operation is an operation of changing a logical address received from the host into a physical address used to actually store data in the non-volatile memory device 124. Wear-leveling is a technique for preventing excessive deterioration of a specific block by uniformly using blocks in the non-volatile memory device 124, for example, may be implemented through a firmware technique that balances erase counts of physical blocks. Garbage collection is a technique for securing usable capacity in the non-volatile memory device 124 by copying valid data of a block to a new block and then erasing the old block. In some implementations, FTL 622 may be implemented in software or hardware form. When the FTL 622 is implemented in software form, program codes or information related to the FTL 622 may be stored in the buffer memory 650 and executed by the CPU 610. When the FTL 622 is implemented in hardware form, a hardware accelerator configured to perform an operation of the FTL 622 may be provided separately from the CPU 610.

The health monitor 624 may be implemented in firmware or software, and may be loaded into the working memory 620. Alternatively, the health monitor 624 may be implemented in hardware. The health monitor 624 may check the retention level of the non-volatile memory device 124. In some implementations, the health monitor 624 may initiate an operation of checking the retention level of the non-volatile memory device 124 under control of the host device 110. The health monitor 624 may start checking the retention level of the non-volatile memory device 124 by referring to the temperature information TD provided from the temperature sensor (123 of FIG. 1).

In some implementations, the health monitor 624 may generate a command CMD to cause the non-volatile memory device 124 to perform an off-cell count operation, and may check the retention level based on the cell count value output from the non-volatile memory device 124. The health monitor 624 may check the retention level based on the time elapsed after the program command is transmitted to the non-volatile memory device 124. The health monitor 624 may check the retention level based on the number of errors detected by the ECC engine 630, whether UECCs have occurred, and the number of UECCs. The CPU 610 may generate a command for controlling the level of a read pass voltage of the non-volatile memory device 124 based on the retention level of the non-volatile memory device 124 checked by the health monitor 624.

The ECC engine 630 may perform error detection and correction functions for data read from the non-volatile memory device 124. The ECC engine 630 may generate an error correction code for correcting a fail bit or an error bit of data transmitted/received to/from the non-volatile memory device 124. More specifically, the ECC engine 630 may generate parity bits (or error correction codes) for write data to be written into the non-volatile memory device 124, and the parity bits generated by the ECC engine 630 may be stored in the non-volatile memory device 124 together with write data. When reading data from the non-volatile memory device 124, the ECC engine 630 may correct errors in the read data using read data and parity bits read from the non-volatile memory device 124 and output read data with the errors corrected.

The ECC engine 630 may detect and correct errors in data to determine whether UECC has occurred. UECC may indicate a state including an error not corrected by the ECC engine 630. The ECC engine 630 may detect UECC during error correction decoding of data received from the non-volatile memory device 124.

The host interface circuit 640 may transmit and receive packets to and from the host device 110.

Packets transmitted from the host device 110 to the host interface circuit 640 may include a command or data to be written to the non-volatile memory device 124, and packets transmitted from the host interface circuit 640 to the host device 110 may include a response to a command or data read from the non-volatile memory device 124. In some implementations, the host interface circuit 640 may be configured to communicate with the host device 110 according to predetermined interface protocols. The predetermined interface protocol may include at least one of various interface protocols such as Advanced Technology Attachment (ATA) interface, Serial ATA (SATA) interface, e-SATA (external SATA) interface, SCSI (Small Computer Small Interface) interface, Serial Attached SCSI (SAS) interface, Peripheral Component Interconnection (PCI) interface, PCI express (PCIe) interface, NVM express (NVMe) interface, IEEE 1394, a universal serial bus (USB) interface, secure digital (SD) card, multi-media card (MMC) interface, an embedded multi-media card (eMMC) interface, Universal Flash Storage (UFS) interface, an embedded Universal Flash Storage (eUFS) interface, compact flash (CF) card interface, or a network interface. The host interface circuit 640 may receive a signal based on a predetermined interface protocol from the host device 110 and operate based on the received signal. Alternatively, the host interface circuit 640 may transmit a signal based on a predetermined interface protocol to the host device 110.

The buffer memory 650 may be a write buffer or a read buffer configured to temporarily store data input to the storage controller 600. Alternatively, the buffer memory 650 may be configured to store various information necessary for the storage controller 600 to operate. For example, the buffer memory 650 may store a mapping table managed by the FTL 622. The buffer memory 650 may store software, firmware, or information related to the FTL 622. In some implementations, the buffer memory 650 may be an SRAM, but the scope of the present disclosure is not limited thereto, and the buffer memory 650 may be implemented with various types of memory devices such as DRAM, MRAM, and PRAM. For concise drawing and convenience of description, the buffer memory 650 is illustrated in FIG. 6 as being included in the storage controller 600, but the scope of the present disclosure is not limited thereto. The buffer memory 650 may be located outside the storage controller 600, and the storage controller 600 may communicate with the buffer memory through a separate communication channel or interface.

The flash interface circuit 660 may transmit data to be written in the non-volatile memory device 124 to the non-volatile memory device 124 or may receive data read from the non-volatile memory device 124. The flash interface circuit 660 may be configured to communicate with the non-volatile memory device 124 according to a predetermined interface protocol. In some implementations, the predetermined interface protocol may include at least one of various interface rules such as a toggle interface and an ONFI interface. In some implementations, the flash interface circuit 660 may communicate with the non-volatile memory device 124 based on a toggle interface. In this case, the flash interface circuit 660 may communicate with the non-volatile memory device 124 through a plurality of channels. In some implementations, each of the plurality of channels may include a plurality of signal lines configured to transmit various control signals (e.g., /CE, CLE, ALE, /WE, /RE, R/B, etc.), data signals (DQ), and a data strobe signal (DQS).

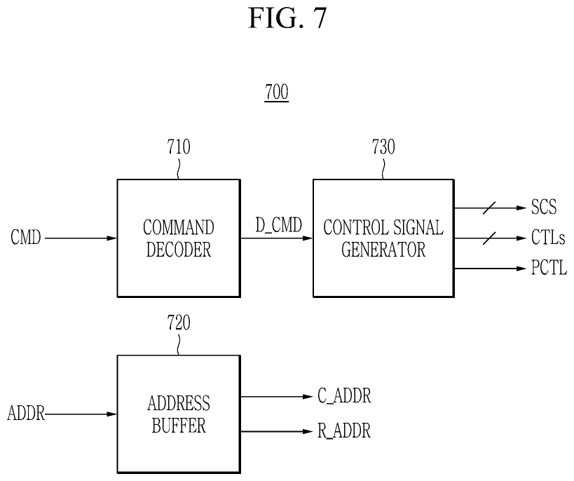

FIG. 7 is a block diagram of a control circuit of a non-volatile memory device according to some implementations.

Referring to FIG. 7, the control circuit 700 may include a command decoder 710, an address buffer 720, and a control signal generator 730.

The command decoder 710 may decode the command signal CMD and provide the decoded command D_CMD to the control signal generator 730.

The address buffer 720 may receive the address signal ADDR, provide the row address R_ADDR among the address signals ADDR to the address decoder (320 in FIG. 3), and provide the column address C_ADDR among the address signals ADDR to the data input/output circuit (340 in FIG. 3).

The control signal generator 730 may receive the decoded command D_CMD, generate control signals CTLs based on an operation indicated by the decoded command D_CMD, provide the control signals CTLs to a voltage generator (360 of FIG. 3), generate the page buffer control signal PCTL, and provide the page buffer control signal PCTL to the page buffer circuit (330 of FIG. 3). The control signal generator 720 may generate a switching control signal SCS based on the decoded command D_CMD and provide the switching control signal SCS to the address decoder 320.

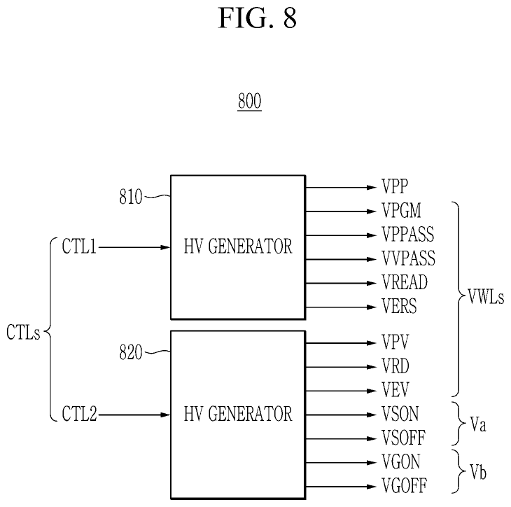

FIG. 8 is a block diagram of a voltage generator of a non-volatile memory device according to some implementations.

Referring to FIG. 8, the voltage generator 800 may include a high voltage generator 810 and a low voltage generator 820.

The high voltage generator 810 may generate a high voltage VPP, a program voltage VPGM, a program pass voltage VPPASS, a verify pass voltage VVPASS, a read pass voltage VREAD, and an erase voltage VRES according to the operation indicated by the command CMD in response to the first control signal CTL1.

The high voltage VPP may be applied to the address decoder (320 in FIG. 3). The program voltage VPGM may be applied to the selected word line, the program pass voltage VPPASS, the program verify pass voltage VVPASS, and the read pass voltage VRPASS may be applied to the unselected word lines, and the erase voltage VRES may be applied to the wells of the memory cell block. The first control signal CTL1 may include a plurality of bits and indicate an operation indicated by the decoded command D_CMD.

The low voltage generator 820 generates a program verify voltage VPV, a read voltage VRD, an erase verify voltage VEV, string select voltages Va, ground select voltages Vb, and a reference voltage VREF according to the operation indicated by the command CMD in response to the second control signal CTL2.

The program verification voltage VPV, the read voltage VRD, and the erase verification voltage VEV may be applied to the selected word line according to an operation. The string select turn-on voltage VSON and the string select turn-off voltage VSOFF may be respectively applied to string select transistors of the selected cell string and the unselected cell string. The ground select turn-on voltage VGON and the ground select turn-off voltage VGOFF may be applied to the ground select transistors of the cell strings. The second control signal CTL2 may include a plurality of bits and indicate an operation indicated by the decoded command D_CMD.

In the above description and in the description that follows, the ‘turn-on’ voltage and the ‘turn-off’ voltage are used for distinguishing voltage levels. Despite their names, these terms do not necessarily refer to the voltage levels that actually turn on or turn off the transistor.

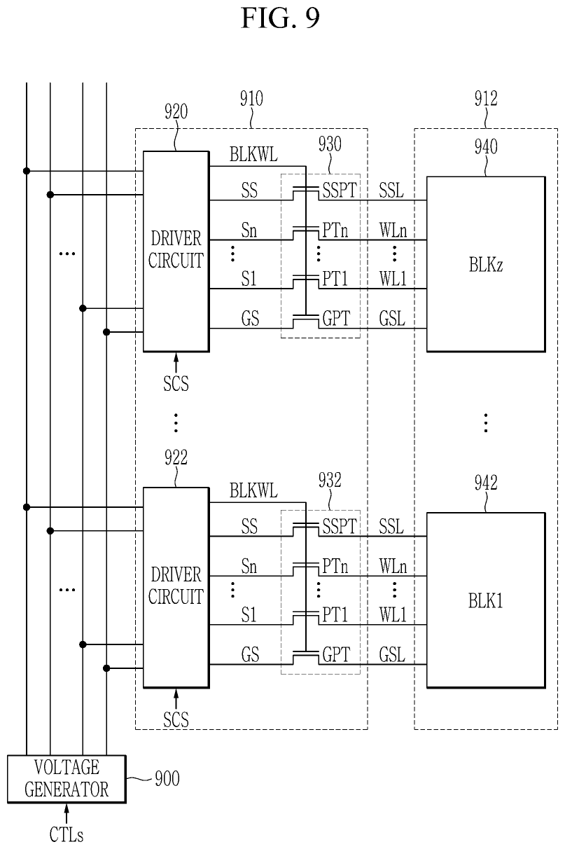

FIG. 9 is a block diagram of a voltage generator, an address decoder, and a memory cell block of a non-volatile memory device according to some implementations.

Referring to FIG. 9, the voltage generator 900 may generate voltages provided to the address decoder 910 and the memory cell array 912 in response to the control signals CTLs. The voltage generator 900 may provide the generated voltages to the connection lines CLs. In some implementations, the voltage generator 900 may apply read pass voltages of different levels over time to one connection line. For example, if the retention level of the memory cell block at the first time point is higher than the retention level of the memory cell block at the second time point after the first time point, the voltage generator 900 may apply a read pass voltage of a first level to the connection line at a first time point, and apply a read pass voltage of a second level higher than the first level to the connection line at a second time point. In some implementations, the voltage generator 900 may simultaneously apply read pass voltages of different levels to a plurality of connection lines. In this case, the driver circuits 920, . . . , 922 may receive read pass voltages of different levels and provide pass voltages of different levels to the corresponding memory cell blocks 940, . . . , 942.

The address decoder 910 may include a plurality of driver circuits 920, . . . , 922 and a plurality of pass switch circuits 930, . . . , 932. The plurality of driver circuits 920, . . . , 922 and the plurality of pass switch circuits 930, . . . , 932 may be connected to corresponding memory cell blocks among the plurality of memory cell blocks 930, . . . , 932. Hereinafter, the driver circuit 920 and the pass switch circuit 930 connected to the memory cell block 930 will be described as an example.

The driver circuit 920 may be connected to connection lines CLs to which voltages generated by the voltage generator 900 are provided. The driver circuit 920 provides voltages provided from the voltage generator 900 to the memory cell array 940 in response to the switching control signals SCS. The driver circuit 920 may provide the high voltage VPP provided from the voltage generator 900 to the pass switch circuit 930. The driver circuit 920 may provide a high voltage to the block word line BLKWL connected to gates of the plurality of pass transistors GPT, PT1, . . . , PTn, and SSPT included in the pass switch circuit 930. The driver circuit 920 may control timing at which the word line voltages VWLs, the string select line voltage Va, and the ground select line voltage Vb are applied.

The driver circuit 920 may provide the word line voltages VWLs provided from the voltage generator 900 to the word lines WL1, . . . , WLn through the driving lines S1, . . . , Sn and the pass transistors PT1, . . . , PTn. The driver circuit 920 may provide the string select line voltage Va to the string select line SSL through the pass transistor SSPT. The driver circuit 920 may provide the ground select line voltage Vb to the ground select line GSL through the pass transistor GPT.

In some implementations, the driver circuit 920 may apply read pass voltages of different levels to a plurality of word lines of the same memory cell block 930 based on the switching control signals SCS. For example, during an operation of reading one page of the memory cell block 930, the driver circuit 920 may apply a first level read pass voltage to the first word line WL1 of the memory cell block 930 and apply a read pass voltage of a second level different from the first level to the n-th word line WLn of the memory cell block 930.

The pass transistors GPT, PT1, . . . , PTn, and SSPT are configured to electrically connect the ground select line GPT, the word lines WL1, . . . , WL8, and the string select line SSL to the corresponding driving lines, in response to the high voltage signal VPP applied through the block word line BLKWL. The pass transistors GPT, PT1, . . . , PTn, and SSPT may include high voltage transistors capable of withstanding high voltages.

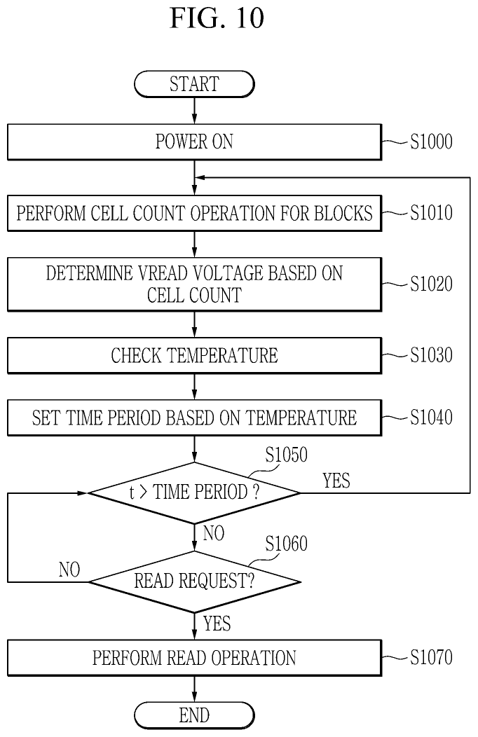

FIG. 10 is flowchart of an operation method of a storage device according to some implementations.

Referring to FIG. 10, the storage controller (121 of FIG. 1) applies power PWR to the non-volatile memory device (124 of FIG. 1) (S1000).

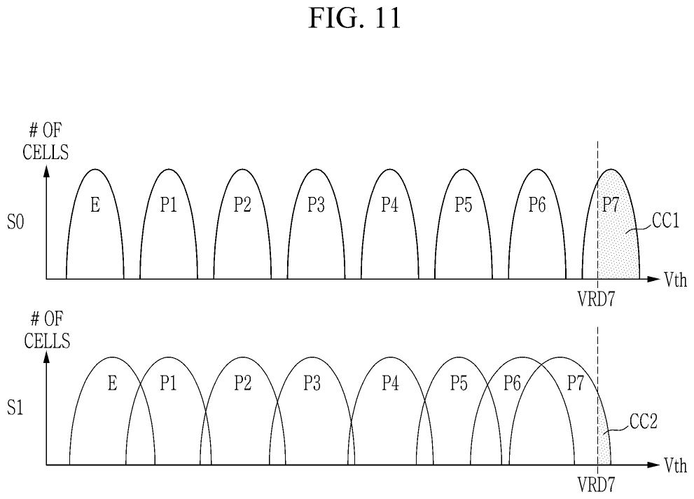

The non-volatile memory device 124 performs a cell count operation on memory cell blocks (S1010). Specifically, the storage controller 121 may provide the non-volatile memory device 124 with a command CMD instructing a cell count operation. In some implementations, the non-volatile memory device 124 may count memory cells (off-cells) blocking a current path to a channel in response to a read voltage (or verify voltage) at a specific time point in response to the provided command (CMD). In some implementations, the non-volatile memory device 124 may perform a cell count operation when the storage device 121 is in an IDLE state. Hereinafter, the cell count operation will be described assuming that it means an off-cell count operation. This cell counting operation will be described with reference to FIG. 11 together.

FIG. 11 is a distribution diagram illustrating off-cell count operation of the non-volatile memory device according to some implementations.

In the distribution diagram of FIG. 11, horizontal axes indicate threshold voltages of memory cells, and vertical axes indicate the number of memory cells. FIG. 11 shows changes in threshold voltages when 3 bits are added to each memory cell. Hereinafter, for ease of description, It is assumed that each of the memory cells of the non-volatile memory device (124 in FIG. 1) is a triple level cell (TLC) configured to store 3 bits.

However, the scope of the present disclosure is not limited thereto, and each of the memory cells may be implemented in various forms, such as SLC (single level cell) that stores 1 bit per cell or MLC (multi-level cell) that stores n-bits (n is a natural number greater than 1) per cell (e.g., TLC (triple level cell), QLC (quad level cell), PLC (penta level cell)).

A first graph SO represents an initial program threshold voltage distribution (e.g., initial threshold voltage distribution) of memory cells of a memory cell block at a first time point, and a second graph S1 shows threshold voltage distribution of memory cells of a memory cell block at a second point in time.

A width between threshold voltage distributions at the first time point may decrease over time, similar to the threshold voltage distribution at the second time point. As time elapses after memory cells are programmed, threshold voltage distributions of memory cells may change due to physical characteristics of memory cells or external factors. In particular, as time elapses after memory cells are programmed, a charge loss in which electrons trapped in a floating gate or a tunnel oxide are released may occur, and thus a threshold voltage distribution may be changed. In addition, while operations such as programming and erasing are repeated on memory cells, tunnel oxide is deteriorated, and charge loss may further increase. Charge loss may reduce the threshold voltage. Accordingly, the threshold voltage distribution S1 may be shifted to the left compared to the initial program threshold voltage distribution S0. That is, as time elapses, the trapped charges may be leaked and the threshold voltages of the memory cells may change. Accordingly, even if the cell count operation is performed with the same voltage, the cell count may be different.

The non-volatile memory device 124 may perform a cell count operation on the first memory cell block at a first time point. For example, the non-volatile memory device 124 may perform an off-cell count operation with respect to the seventh read voltage VRD7. An off-cell count (i.e., a first cell count CC1) for a seventh read voltage RD7 of the first memory cell block at the first time point may be a first value. The non-volatile memory device 124 may transmit the first cell count CC1 having the first value to the storage controller 121. The storage controller 121 may store the received first cell count CC1 in association with the first memory cell block.

The non-volatile memory device 124 may perform a cell count operation on the first memory cell block at a second time point. For example, the non-volatile memory device 124 may perform an off-cell count operation with respect to the seventh read voltage VRD7. The off-cell count (i.e., the second cell count CC2) for the seventh read voltage RD7 of the first memory cell block at the second time point may be a second value. The non-volatile memory device 124 may transmit the second cell count CC2 having the second value to the storage controller 121. The storage controller 121 may store the received second cell count CC2 in association with the first memory cell block.

In the above, it has been described that the non-volatile memory device 124 performs an off-cell count operation, but the non-volatile memory device 124 may count memory cells (on-cells) forming a current path in a channel in response to a read voltage (or verify voltage) at a specific time point in response to the provided command CMD.

Back to FIG. 10, the storage controller 121 determines read pass voltages for memory cell blocks based on the cell count value (S1020). When the cell count value is greater, the storage controller 121 may determine the read pass voltage at a lower level. For example, the storage controller 121 may determine read pass voltages based on cell count values, so that the read pass voltage when the cell count value is the first value is smaller than the read pass voltage when the cell count value is a second value smaller than the first value,

In some implementations, the storage controller 121 may determine read pass voltages for memory cell blocks, receive a read request for the memory cell blocks whose read pass voltages are determined in step S1060, and perform a read operation according to step S1070.

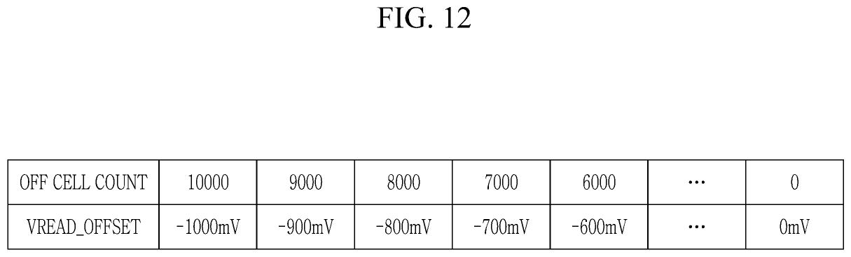

FIG. 12 is a table of offset values of a read pass voltage corresponding to off-cell count values.

Referring to FIG. 12, when the off-cell count value is 0, the read pass voltage VREAD may have a preset voltage level. When the off-cell count value is 6000 or more, the storage controller 121 may determine the read pass voltage VREAD as a voltage 600 mV lower than the preset voltage level. When the off-cell count value is greater, the storage controller 121 may determine the read pass voltage VREAD so that the read pass voltage has a low voltage level.

Back to FIG. 10, the storage controller 121 checks the temperature information TD provided from the temperature sensor 123 (S1030).

The storage controller 121 sets a set time period according to the temperature information (S1040). For example, the storage controller 121 may set a time period as shown in Table 1 below according to a temperature value according to the temperature information TD.

TABLE 1

| temperature value | duration | |
|---|---|---|
| T ≤ 0 | 7 | days |
| 0 < T ≤ 20 | 3 | days |
| 20 < T ≤ 40 | 1 | day |
| 40 < T ≤ 60 | 12 | hours |
| 60 < T ≤ 80 | 4 | hours |
| 80 < T | 1 | hour |

The storage controller 121 determines whether the time elapsed from setting the time period or the time elapsed from checking the temperature information exceeds the set time period (S1050). For example, the storage controller 121 may determine whether the time that has elapsed since checking the temperature information TD having a temperature value of 30 exceeds 12 hours.

If the time elapsed from setting the time period or the time elapsed from checking the temperature information exceeds the set time period, the storage controller 121 performs step S1010.

If the time that has elapsed since the time period was set or the time that has elapsed since the temperature information was checked is less than or equal to the set time period, the storage controller 121 determines whether a read request is received from the host device 110 (S1060).

When a read request is received, the storage controller 121 controls the non-volatile memory device 124 to perform a read operation (S1070). If there is no read request, the storage controller 121 may check the time that has elapsed since the time period was set or the time that has elapsed since the temperature information was checked.

Although the steps S1010, . . . , and S1050 have been described as being performed by the storage controller 121 above, the steps S1010, . . . , and S1050 may be performed by the control circuit (350 in FIG. 3) of the non-volatile memory device.

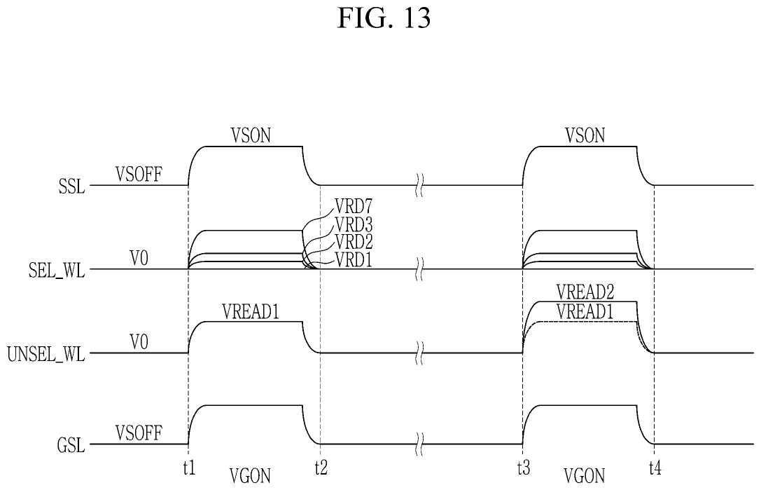

FIG. 13 is a timing diagram of voltages applied to cell strings of FIG. 5 according to an operation method of a storage device according to some implementations.

In FIG. 13, a horizontal axis indicates time, and a vertical axis shows voltages of a string select line SSL, a selected word line SEL_WL, an unselected word line UNSEL_WL, and a ground select line GSL.

Between the first time point t1 and the second time point t2, a develop operation for a read operation may be performed, and a latch operation may be performed after the second time point t2. The address decoder (320 in FIG. 3) may apply a string select turn-on voltage VSON to selected string select lines. The string select turn-on voltage VSON may be a voltage for turning on the string select transistors (SST1, SST2, and SST3 of FIG. 5). The string select turn-on voltage VSON may be a power supply voltage or a high voltage having a higher level than the power supply voltage. The address decoder 320 may maintain voltages of unselected string select lines as the string select turn-off voltage VSOFF.

The address decoder 320 may apply the first read pass voltage VREAD1 to the unselected word line UNSEL_WL. The first read pass voltage VREAD1 may be a voltage for turning on memory cells. The first read pass voltage VREAD1 may have a first voltage level. The address decoder 320 may apply read voltages VRD1 to VRD7 to the selected word line SEL_WL.

The address decoder 320 may apply the ground select turn-on voltage VGON to the selected ground select line. The ground select turn-on voltage VGON may be voltages for turning on the ground select transistors GST. The ground select turn-on voltage VGON may be a power supply voltage or high voltages higher than the power supply voltage. The address decoder 320 may maintain the voltage of the unselected ground select line as the ground select turn-off voltage VGOFF.

During the develop operation, the string select transistors SST1, SST2, and SST3 of the selected plane of the selected memory cell block may be turned on by the string select turn-on voltage VSON. The ground select transistors GST of the selected plane may be turned on by the ground select turn-on voltage VGON. Memory cells connected to unselected word lines in the selected plane may be turned on by the first read pass voltage VREAD1. Memory cells connected to the selected word line in the selected plane may be turned on or off by the read voltages VRD1, VRD7.

For example, memory cells in which ‘1’ is written as the least significant bit (LSB) may be turned on by the read voltage VRD1. Voltages of bit lines corresponding to the turned-on cells are discharged to the common source line CSL. Accordingly, voltages of bit lines corresponding to turned-on cells decrease during a develop operation. Memory cells in which ‘0’ is written as the least significant bit (LSB) may be turned off by the read voltage VRD1. Voltages of bit lines corresponding to turned-off cells are not discharged to the common source line CSL. Accordingly, the voltages of the bit lines corresponding to the turned-off cells are maintained without decreasing during the develop operation.

After the second time point t2, the address decoder 320 may apply the string select turn-off voltage VSOFF to the string select lines. The address decoder 320 may apply the word line voltage V0 to the unselected word line UNSEL_WL and the selected word line SEL_WL. The word line voltage V0 may be a ground voltage or a voltage having a level similar to the ground voltage. The address decoder 320 may apply the ground select turn-off voltage VGOFF to the ground select line.

It is assumed that steps S1010 and S1020 are performed between the second time point t2 and the third time point t3. As time elapses from the second time point t2, charges trapped in the memory cells may flow out, and thus the threshold voltages of the memory cells may change. Accordingly, the off-cell count values at the first time point t1 and the third time point t3 may be different, and the read pass voltages VREAD1 and VREAD2 may also be determined to have different voltage levels.

Between the third time point t3 and the fourth time point t4, a develop operation for a read operation may be performed, and a latch operation may be performed after the fourth time point t4. The address decoder 320 may apply a string select turn-on voltage VSON to selected string select lines. The address decoder 320 may maintain voltages of unselected string select lines as the string select turn-off voltage VSOFF.

The address decoder 320 may apply the second read pass voltage VREAD2 to the unselected word line UNSEL_WL. The second read pass voltage VREAD2 may be a voltage for turning on memory cells. The second read pass voltage VREAD1 may have a second voltage level higher than the level of the first read pass voltage VREAD2. The address decoder 320 may apply read voltages VRD1 to VRD7 to the selected word line SEL_WL.

The address decoder 320 may apply the ground select turn-on voltage VGON to the selected ground select line. The address decoder 320 may maintain the voltage of the unselected ground select line as the ground select turn-off voltage VGOFF.

Although not shown in FIG. 13, a ground voltage or a low voltage having a level similar to the ground voltage may be applied to the common source line CSL.

A method of operating a storage device according to some implementations, may prevent read disturb deterioration by applying a low read pass voltage VREAD1 when memory cells are initially narrowly distributed, improve read characteristics of the non-volatile memory device 124 by applying a read pass voltage VREAD2 higher than the read pass voltage VREAD1 after retention deterioration progresses. That is, since the higher the off-cell count value, the less the retention deterioration progressed, the storage device performs a read operation with a low read pass voltage VREAD1, as the off-cell count value decreased, the retention degradation progressed further, the storage device may perform a read operation with a high read pass voltage VREAD2 to prevent execution of defensive code or UECC.

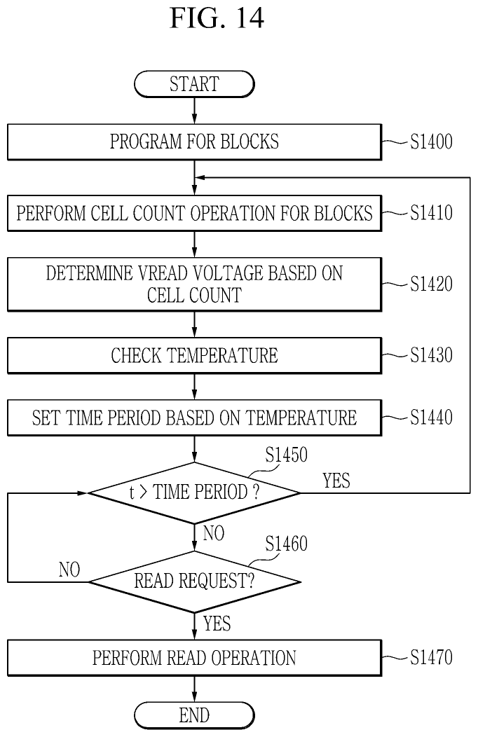

FIG. 14 is a flowchart illustrating an operation method of a storage device according to some implementations.

Among the steps of the method of operating the storage device of FIG. 14, descriptions of steps identical to or similar to those of the method of operating the storage device described in FIG. 10 will be omitted.

Referring to FIG. 14, the non-volatile memory device (124 of FIG. 1) performs a program operation on memory cell blocks included in the memory cell array (125 of FIG. 1) (S1400).

The non-volatile memory device 124 performs a cell count operation on memory cell blocks (S1410). In some implementations, the non-volatile memory device 124 may perform a cell count operation when the storage device (121 of FIG. 1) is in an IDLE state.

The storage controller 121 determines read pass voltages for memory cell blocks based on the cell count value (S1420). In some implementations, the storage controller 121 may determine read pass voltages for memory cell blocks, receive a read request for the memory cell blocks whose read pass voltages are determined in step 51460, and perform a read operation according to step 51470.

The storage controller 121 checks the temperature information TD provided from the temperature sensor 123 (S1430). The storage controller 121 sets a set time period according to the temperature information (S1440).

The storage controller 121 determines whether the time elapsed from setting the time period or the time elapsed from checking the temperature information exceeds the set time period (S1450). If the time elapsed from setting the time period or the time elapsed from checking the temperature information exceeds the set time period, the storage controller 121 performs step S1410.

If the time that has elapsed since the time period was set or the time that has elapsed since the temperature information was checked is less than or equal to the set time period, the storage controller 121 determines whether a read request is received from the host device 110 (S1460). When a read request is received, the storage controller 121 controls the non-volatile memory device 124 to perform a read operation (S1470).

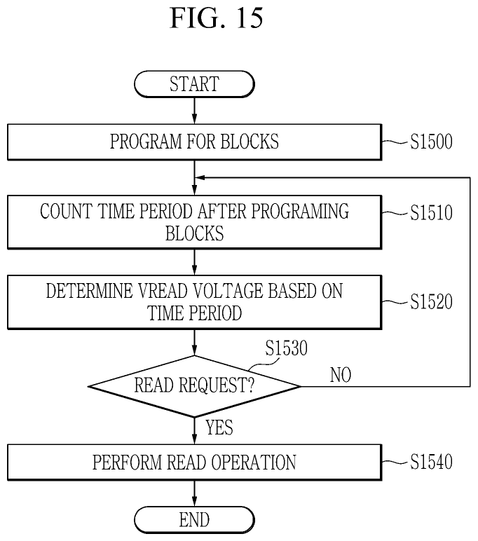

FIG. 15 is a flowchart illustrating an operation method of a storage device according to some implementations.

Among the steps of the method of operating the storage device of FIG. 15, descriptions of steps identical to or similar to those of the method of operating the storage device described in FIG. 10 will be omitted.

Referring to FIG. 15, the non-volatile memory device (124 of FIG. 1) performs a program operation on memory cell blocks included in the memory cell array (125 of FIG. 1) (S1500).

The storage device 121 counts a time period after performing a program operation on memory cell blocks (S1510). The storage device 121 may store the time at which the program operation was performed on each of the memory cell blocks and count the time elapsed from the stored time.

The storage controller 121 determines read pass voltages for the memory cell blocks based on the time period (S1520). In detail, the storage controller 121 may check the retention level based on the time period and determine the read pass voltage based on the retention level. For example, the storage controller 121 may determine that the retention level is lower as the length of the time period is longer, and determine the read pass voltage with a higher level. The storage controller 121 may determine read pass voltages based on the length of the time period, so that the read pass voltage when the length of the time period is a first value is greater than the read pass voltage when the length of the time period is a second value smaller than the first value.

the storage controller 121 determines whether a read request is received from the host device 110 (S1530). When a read request is received, the storage controller 121 controls the non-volatile memory device 124 to perform a read operation (S1540).

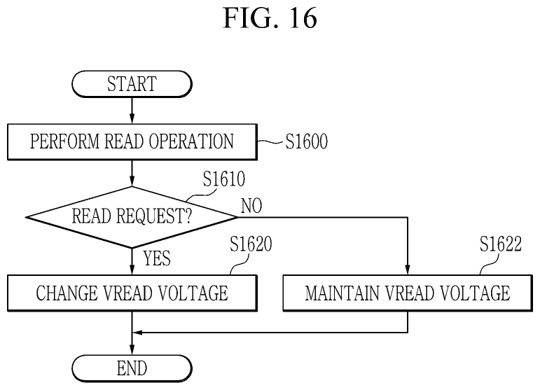

FIG. 16 is a flowchart illustrating an operation method of a storage device according to some implementations.

Among the steps of the method of operating the storage device of FIG. 16, descriptions of steps identical to or similar to those of the method of operating the storage device described in FIG. 10 will be omitted.

Referring to FIG. 16, the storage device (121 of FIG. 1) performs a read operation on the non-volatile memory device (124 of FIG. 1) (S1600).

The storage device 121 detects and corrects errors in data read from the non-volatile memory device 124 to determine whether UECC has occurred (S1610). The storage device 121 may perform error detection and correction functions for read data read from the non-volatile memory device 124. The storage device 121 may detect UECC during error correction decoding of data received from the non-volatile memory device 124.

If it is determined that UECC has occurred, the storage controller 121 changes read pass voltages for the memory cell blocks (S1620). The storage controller 121 may determine the read pass voltage based on the number and frequency of UECC occurrences for each memory cell block. In some implementations, the storage controller 121 may determine the read pass voltage to have a higher level as the number of occurrences of UECC is greater. For example, the storage controller 121 may determine read pass voltages based on the number of occurrences of UECC, so that the read pass voltage when the number of occurrences of UECC is a first value is greater than the read pass voltage when the number of occurrences of UECC is a second value smaller than the first value,

In some implementations, the storage controller 121 may increase a read pass voltage of a memory cell block in which UECC has occurred. The storage controller 121 may increase the read pass voltage whenever UECC occurs.

If it is determined that UECC has not occurred, the storage controller 121 maintains read pass voltages for the memory cell blocks (S1622).

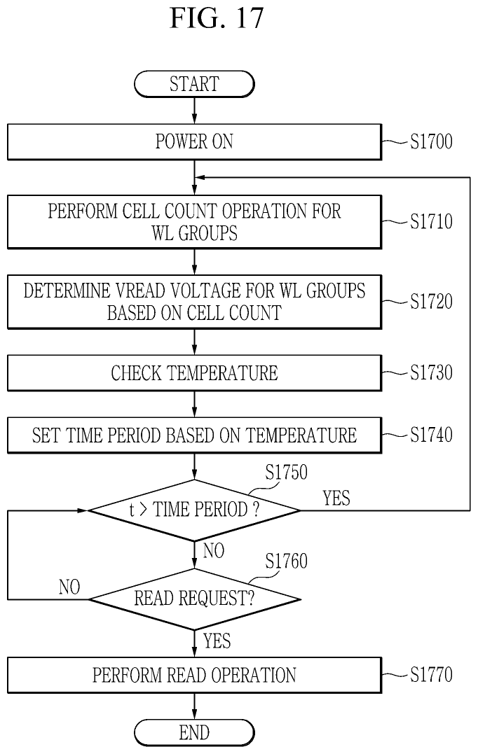

FIG. 17 is a flowchart illustrating an operation method of a storage device according to some implementations.

Among the steps of the method of operating the storage device of FIG. 17, descriptions of steps identical to or similar to those of the method of operating the storage device described in FIG. 10 will be omitted.

Referring to FIG. 17, the storage controller (121 of FIG. 1) applies power PWR to the non-volatile memory device (124 of FIG. 1) (S1700).

The non-volatile memory device 124 performs a cell count operation on word line groups within a memory cell block (S1710). Specifically, the storage controller 121 may provide the non-volatile memory device 124 with a command CMD instructing a cell count operation. In some implementations, in response to the provided command CMD, the non-volatile memory device 124 may count memory cells (off-cells) blocking a current path to a channel in response to a read voltage (or verify voltage) at a specific time point. In some implementations, the non-volatile memory device 124 may perform a cell count operation for each word line group in response to the provided command CMD. For example, one memory cell block of the non-volatile memory device 124 may include a plurality of word line groups, and each word line group may include a plurality of word lines.

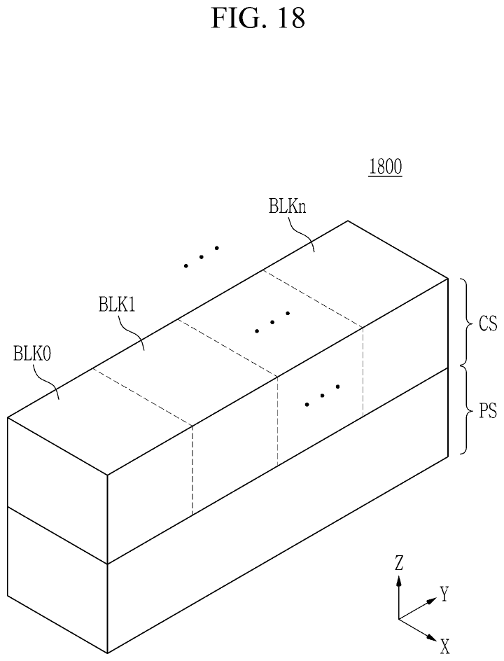

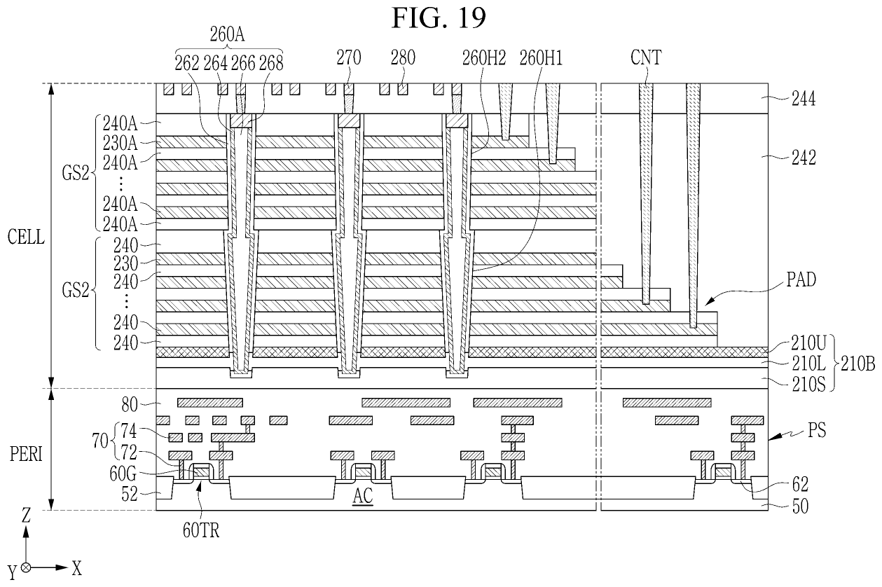

These word line groups may correspond to a plurality of gate electrodes disposed in a physically identifiable channel structure. This will be described with reference to FIGS. 18 and 19.

FIG. 18 is a perspective view illustrating a semiconductor device according to some implementations, and FIG. 19 is a cross-sectional view illustrating an example of a semiconductor device according to some implementations.

Referring to FIGS. 18 and 19, a semiconductor device 1800 may include a cell array structure CS and a peripheral circuit structure PS that overlap each other in a vertical direction Z. The cell array structure CS may include the memory cell array 310 described with reference to FIG. 3, and the peripheral circuit structure PS may include the peripheral circuits 320, . . . 360 described with reference to FIG. 3. can

The cell array structure CS may include a plurality of memory cell blocks BLK1, BLK2, . . . , BLKn. Each of the plurality of memory cell blocks BLK1, BLK2, . . . , BLKn may include three-dimensionally arranged memory cells. The cell array structure CS may include the cell region CELL, and the peripheral circuit structure PS may include a peripheral circuit transistor 60TR and a peripheral circuit wiring structure 70 disposed on the substrate 50. An active region AC may be on the substrate 50 by the device isolation layer 52, and a plurality of peripheral circuit transistors 60TR may be on the active region AC. The plurality of peripheral circuit transistors 60TR may include a peripheral circuit gate 60G and a source/drain region 62 disposed on a portion of the substrate 50 on both sides of the peripheral circuit gate 60G.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or an epitaxial layer. In other implementations, the substrate 50 may include a silicon-on-insulator (SOI) substrate or a germanium-on-insulator (GeOI) substrate.

The peripheral circuit wiring structure 70 may include a plurality of peripheral circuit contacts 72 and a plurality of peripheral circuit wiring layers 74. An interlayer insulating layer 80 covering the peripheral circuit transistor 60TR and the peripheral circuit wiring structure 70 may be disposed on the substrate 50. The plurality of peripheral circuit wiring layers 74 may have a multilayer structure including a plurality of metal layers disposed at different vertical levels. Although FIG. 19 shows that the plurality of peripheral circuit wiring layers 74 are all formed at the same height, alternatively, the peripheral circuit wiring layer 74 disposed on some levels (e.g., disposed on the top level) may be formed to a height greater than that of the peripheral circuit wiring layers 74 disposed on the other levels.

A base structure 210B may be disposed on the peripheral circuit structure PS, the base structure 210B may include a base substrate 210S, a lower base layer 210L, and an upper base layer 210U sequentially disposed on the interlayer insulating layer 80.

The base substrate 210S may include a semiconductor material such as silicon. The lower base layer 210L may include impurity-doped polysilicon or undoped polysilicon, and the upper base layer 210U may include impurity-doped polysilicon or undoped polysilicon. The lower base layer 210L may correspond to the common source line CSL described with reference to FIG. 5. The upper base layer 210U may serve as a support layer to prevent the mold stack from collapsing or collapsing in a process of removing the sacrificial material layer for forming the lower base layer 210L.

A first gate stack GS1 may be disposed on the base structure 210B, and a second gate stack GS2 may be disposed on the first gate stack GS1. The first gate stack GS1 may include a plurality of first gate electrodes 230 and a plurality of first insulating layers 240 that are alternately disposed, and the second gate stack GS2 may include a plurality of second gate electrodes 230A and a plurality of second insulating layers 240A that are alternately disposed.

The plurality of channel structures 260A may be positioned inside the first channel hole 260H1 penetrating the first gate stack GS1 and the second channel hole 260H2 penetrating the second gate stack GS2. The plurality of channel structures 260A may have a shape protruding outward from a boundary between the first channel hole 260H1 and the second channel hole 260H2.

The plurality of channel structures 260A may pass through the upper base layer 210U and the lower base layer 210L and contact the base substrate 210S. A portion of the gate insulating layer 262 may be removed at the same level as the lower base layer 210L, and the channel layer 264 may contact the extension portion 210LE of the lower base layer 210L. The side wall portion 262S and the bottom portion 262L of the gate insulating layer 262 are spaced apart from each other with the extension portion 210LE of the lower base layer 210L interposed therebetween, the bottom portion 262L of the gate insulating layer 262 surrounds the bottom surface of the channel layer 264, and the channel layer 264 may be electrically connected to the lower base layer 210L instead of directly contacting the base substrate 210S.

The plurality of first gate electrodes 230 included in the first gate stack GS1 and the plurality of second gate electrodes 230A included in the second gate stack GS2 may respectively correspond to different word line groups. For example, the first word line group may include a plurality of first gate electrodes 230 included in the first gate stack GS1, the second word line group may include a plurality of second gate electrodes 230A included in the second gate stack GS2.

Although it has been described above that a plurality of word line groups correspond to gate electrodes included in physically separated gate stacks, implementations are not limited thereto. For example, a plurality of word line groups may be classified according to a distance from a ground select line GSL, a distance from a string select line SSL, or a distance from a base structure 210B. Also, the number of word lines included in each of the plurality of word line groups may be the same or different.

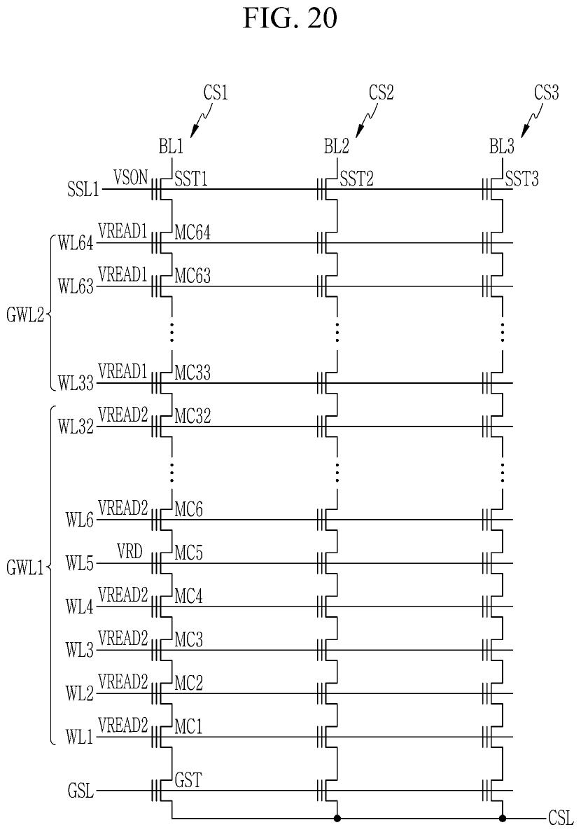

FIG. 20 shows cell strings included in a memory cell block and voltages applied to the cell strings according to some implementations.

Referring to FIG. 20, during read operation and/or program verification operation, the non-volatile memory device may read data stored in memory cells connected to the selected word line WL5, by applying the read voltage VRD to the selected word line WL5 connected to the selected cell strings CS1, CS2, and CS3,

Predetermined turn-on voltages VSON and VGON may be applied to the first string selection line SSL1, which is a selection string selection line, and the ground selection line GSL, which is a selection ground selection line. A read voltage VRD may be applied to the selected word line, the fifth word line WL5. The second read pass voltage VREAD2 may be applied to the unselected word lines WL1, . . . , WL4, WL6 . . . , and WL32 included in the first word line group GWL1. A first read pass voltage VREAD1 different from the second read pass voltage VREAD2 may be applied to the unselected word lines WL33, . . . , and WL64 included in the second word line group GWL2. In some implementations, the second read pass voltage VREAD2 applied to the upper second word line group GWL2 (or a word line group adjacent to the string select line (SSL1)) may be set higher than the second read pass voltage VREAD2 applied to the lower first word line group GWL1 (or a word line group adjacent to the ground select line (GSL)).

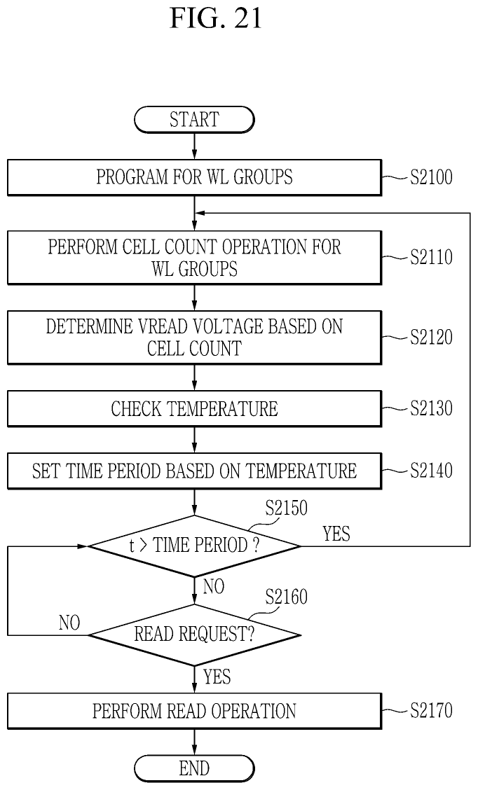

FIG. 21 is a flowchart illustrating an operation method of a storage device according to some implementations.

Among the steps of the method of operating the storage device of FIG. 21, descriptions of steps identical to or similar to those of the method of operating the storage device described in FIG. 17 will be omitted.

Referring to FIG. 21, the non-volatile memory device (124 of FIG. 1) performs a program operation on memory cell blocks included in the memory cell array (125 of FIG. 1) (S2100).

The non-volatile memory device 124 performs a cell count operation on word line groups within memory cell blocks (S2110). In some implementations, the non-volatile memory device 124 may perform a cell count operation when the storage device (121 of FIG. 1) is in an IDLE state.

The storage controller 121 determines a read pass voltage for each of the word line groups based on the cell count value (S2120). In some implementations, the storage controller 121 may determine a read pass voltage for each of the word line groups, receive a read request for memory cell blocks including word line groups whose read pass voltages are determined in operation S2160, and perform a read operation according to step S2170.

The storage controller 121 checks the temperature information TD provided from the temperature sensor 123 (S2130). The storage controller 121 sets a set time period according to the temperature information (S2140).

The storage controller 121 determines whether the time elapsed from setting the time period or the time elapsed from checking the temperature information exceeds the set time period (S2150). If the time elapsed from setting the time period or the time elapsed from checking the temperature information exceeds the set time period, the storage controller 121 performs step S2110.

If the time elapsed from setting the time period or the time elapsed from checking the temperature information is less than or equal to the set time period, the storage controller 121 determines whether a read request is received from the host device 110 (S2160). When a read request is received, the storage controller 121 controls the non-volatile memory device 124 to perform a read operation (S2170).

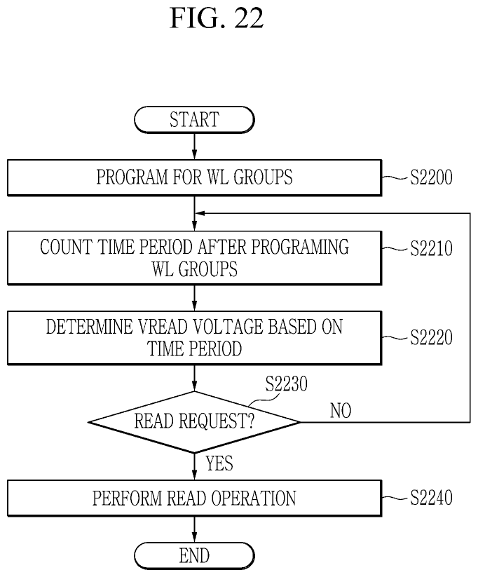

FIG. 22 is a flowchart illustrating an operation method of a storage device according to some implementations.

Among the steps of the method of operating the storage device of FIG. 22, descriptions of steps identical to or similar to those of the method of operating the storage device described in FIG. 17 will be omitted.

Referring to FIG. 22, the non-volatile memory device (124 of FIG. 1) performs a program operation on memory cells connected to the word line group of the memory cell array (125 of FIG. 1) (S2200).

The storage device 121 counts a time period after performing a program operation on memory cells connected to the word line group (S2210). The storage device 121 may store the time at which the program operation was performed for each of the word line groups, and may count the time elapsed from the stored time.

The storage controller 121 determines read pass voltages for word line groups based on the time period (S2220). The storage controller 121 may determine the read pass voltage at a higher level as the length of the time period is longer. For example, the storage controller 121 may determine read pass voltages based on the length of the time period, so that the read pass voltage when the length of the time period is a first value is greater than the read pass voltage when the length of the time period is a second value smaller than the first value.

the storage controller 121 determines whether a read request is received from the host device 110 (S2230). When a read request is received, the storage controller 121 controls the non-volatile memory device 124 to perform a read operation (S2240).

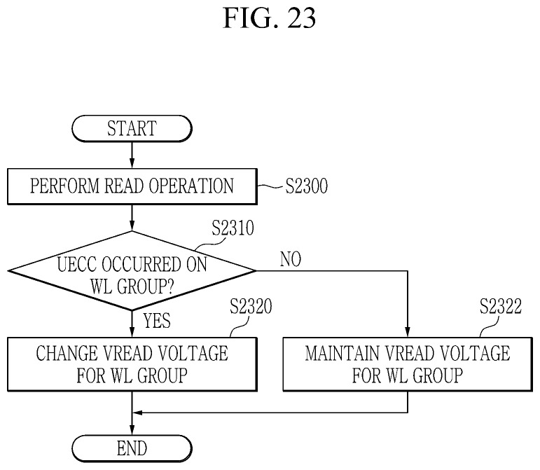

FIG. 23 is a flowchart illustrating an operation method of a storage device according to some implementations.

Among the steps of the method of operating the storage device of FIG. 23, descriptions of steps identical to or similar to those of the method of operating the storage device described in FIG. 17 will be omitted.

Referring to FIG. 23, the storage device (121 of FIG. 1) performs a read operation on the non-volatile memory device (124 of FIG. 1) (S2300).

The storage device 121 determines whether UECC has occurred by detecting and correcting errors in data read from the non-volatile memory device 124 (S2310). The storage device 121 may perform error detection and correction functions for read data read from the non-volatile memory device 124. The storage device 121 may detect UECC during error correction decoding of data received from the non-volatile memory device 124.

If it is determined that UECC has occurred, the storage controller 121 changes the read pass voltage for the word line group (S2320). The storage controller 121 may determine the read pass voltage based on the number and frequency of UECC occurrences for each word line group. In some implementations, the storage controller 121 may determine the read pass voltage to have a higher level as the number of occurrences of UECC is greater. For example, the storage controller 121 may determine read pass voltages based on the number of occurrences of UECC, so that the read pass voltage when the number of occurrences of UECC is a first value is greater than the read pass voltage when the number of occurrences of UECC is a second value smaller than the first value,

In some implementations, the storage controller 121 may increase a read pass voltage of a word line group in which UECC has occurred. The storage controller 121 may increase the read pass voltage whenever UECC occurs.

If it is determined that UECC has not occurred, the storage controller 121 maintains read pass voltages for the memory cell blocks (S2322).

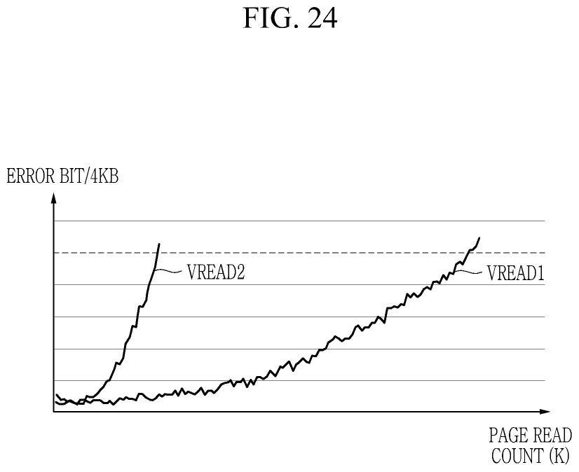

FIG. 24 is a graph illustrating the number of error bits per 4 KB according to the number of page reads for each read pass voltage according to some implementations.

Referring to FIG. 24, a read pass voltage VREAD2 is higher than a read pass voltage VREAD1. When the number of page reads is 0, the difference in the number of error bits according to the read pass voltages VREAD1 and VREAD2 is small. When the number of page reads increases, the number of error bits according to the read pass voltage VREAD2 is greater than the number of error bits according to the read pass voltage VREAD1. That is, when the low read pass voltage VREAD1 is used, generation of error bits can be prevented.

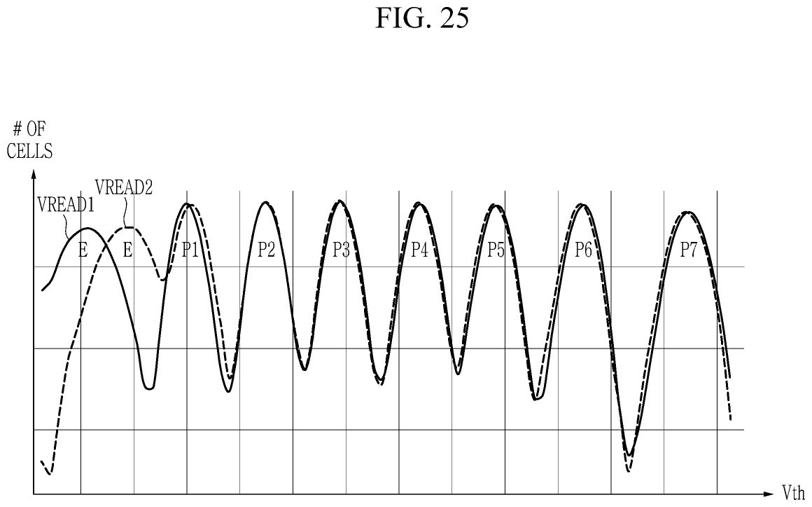

FIG. 25 is a graph illustrating threshold voltage distribution for each read pass voltage according to some implementations.

In the graph of FIG. 25, horizontal axes indicate threshold voltages of memory cells, and vertical axes indicate the number of memory cells.

Referring to FIG. 25, a read pass voltage VREAD2 is higher than a read pass voltage VREAD1. The threshold voltage distribution when the page read operation is performed with the read pass voltage (VREAD1) is uneven compared to the threshold voltage distribution when the page read operation is performed with the read pass voltage (VREAD2). Specifically, the threshold voltage distribution of the memory cells having the first state E when page read operation is performed with the read pass voltage (VREAD2) is shifted closer to the threshold voltage distribution of the memory cells having the second state P1. That is, when a low read pass voltage VREAD1 is used, the threshold voltage distribution may be prevented from shifting.

Therefore, in the case of using the low read pass voltage VREAD1, read disturb deterioration can be prevented.

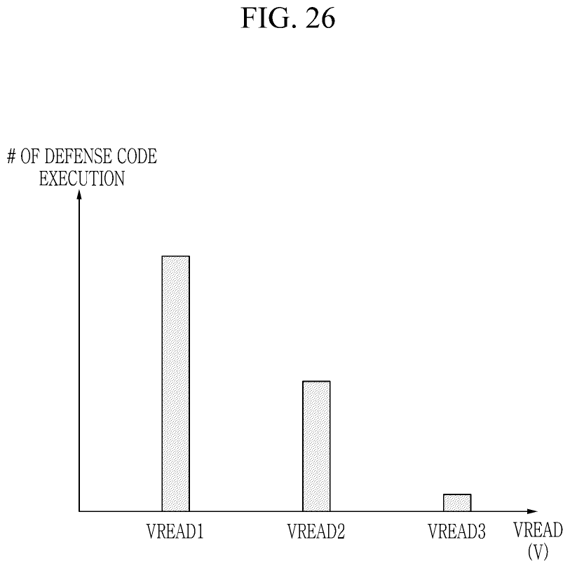

FIG. 26 is a graph illustrating the number of executions of defense codes for each read pass voltage according to some implementations.

In the graph of FIG. 26, the horizontal axis indicates the magnitude of the read pass voltage, and the vertical axes indicate the number of executions of defense codes.

Referring to FIG. 26, a read pass voltage VREAD3 is higher than a read pass voltage VREAD2, and the read pass voltage VREAD2 is higher than a read pass voltage VREAD1. The number of executions of the defense code is smaller when the page read operation is performed with the read pass voltage VREAD2 than the number of executions of the defense code when the page read operation is performed with the read pass voltage VREAD1. The number of executions of the defense code is smaller when the page read operation is performed with the read pass voltage VREAD3 than the number of executions of the defense code when the page read operation is performed with the read pass voltage VREAD2. That is, in order to reduce the number of executions of defense codes, it is required to apply a higher read pass voltage VREAD.

According to some implementations, since the voltage level of the read pass voltage VREAD provided to a memory cell block or word line having a relatively low retention level is greater than that of the read pass voltage VREAD provided to a memory cell block or word line having a relatively high retention level, read disturb deterioration due to a read pass voltage VREAD of a memory cell block having a relatively high retention level or a memory cell connected to a word line is prevented, and a read error (e.g., execution of defense code, generation of UECC, etc.) of a memory cell block having a relatively low retention level or a memory cell connected to a word line may be prevented.

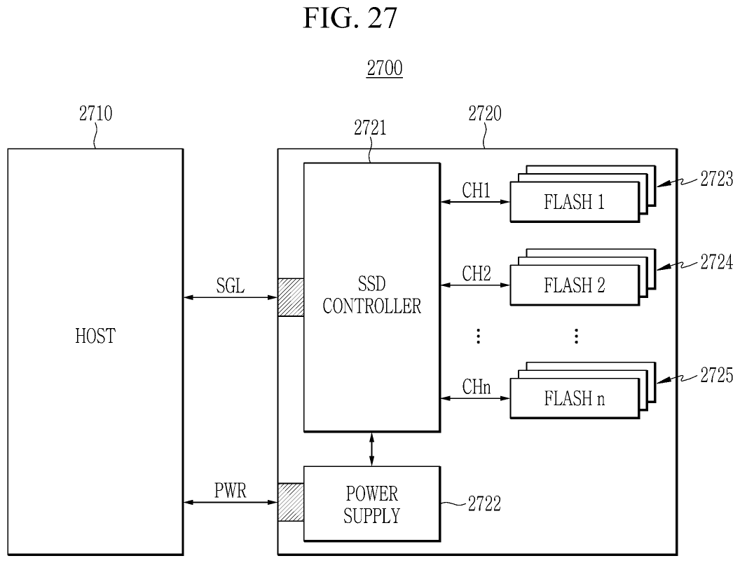

FIG. 27 is a block diagram illustrating an example of a solid-state drive (SSD) system applied a non-volatile memory device according to some implementations.

Referring to FIG. 27, an SSD system 2700 may include a host 2710 and an SSD 2720.

The SSD 2720 may be implemented using the implementations described with reference to FIGS. 1 to 26. The SSD 2720 may exchange signals with the host 2710 through a signal connector (SGL) and receive power through a power connector (PWR).

The SSD 2720 may receive a firmware image download command and a firmware image to be downloaded through the signal connector SGL.

The SSD 2720 may include a controller 2721, an auxiliary power supply 2722, and a plurality of memory systems 2723, 2324, and 2325. Each of the plurality of memory systems 2723, 2324, and 2325 may include one or more flash memory devices as storage devices. Also, each flash memory device may include one or more dies (DIE), and one or more blocks may be disposed in each die (DIE).

The controller 2721 may communicate with the plurality of memory systems 2723, 2324, and 2325 through a plurality of channels Ch1, . . . , Chn. The controller 2721 may change the level of the read pass voltage applied to the memory cell block or word line group based on the retention levels of the memory cell blocks or word line groups included in the plurality of memory systems 2723, 2324, and 2325,

Therefore, read disturb deterioration due to a read pass voltage of a memory cell block having a relatively high retention level or a memory cell connected to a word line is prevented, and a read error of a memory cell block having a relatively low retention level or a memory cell connected to a word line may be prevented.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While aspects of example implementations have been particularly shown and described, it will be understood that various changes in form and details may be made therein without departing from the spirit and scope of the following claims.

What is claimed is:

1. A non-volatile memory device, comprising:
a memory cell array comprising a plurality of memory cell blocks; and
an address decoder connected to the memory cell array through a plurality of word lines, wherein the address decoder is configured to
apply a plurality of read pass voltages of different levels to multiple memory cell blocks, respectively, among the plurality of memory cell blocks, and
for a selected memory cell block among the plurality of memory cell blocks, apply a corresponding read pass voltage to a plurality of unselected word lines of the selected memory cell block.

2. The non-volatile memory device of claim 1, wherein
the address decoder is configured to apply, to a memory cell block in which retention degradation is more advanced than in the selected memory cell block, a read pass voltage that is higher than the read pass voltage corresponding to the selected memory cell block.

3. The non-volatile memory device of claim 1, wherein
the address decoder is configured to apply, to a memory cell block having a lower off-cell count value than the selected memory cell block, a read pass voltage that is higher than the read pass voltage corresponding to the selected memory cell block.

4. The non-volatile memory device of claim 1, wherein
the address decoder is configured to apply, to a memory cell block in which a greater number of read errors have occurred than in the selected memory cell block, a read pass voltage that is higher than the read pass voltage corresponding to the selected memory cell block.

5. The non-volatile memory device of claim 1, wherein
the address decoder is configured to change a read pass voltage level of a memory cell block in which an uncorrectable error correction code (UECC) is generated, and apply the changed read pass voltage to the memory cell block in which the uncorrectable error correction code (UECC) is generated.

6. The non-volatile memory device of claim 1, wherein
the address decoder is configured to apply a read pass voltage having a first level to a first memory cell block among the plurality of memory cell blocks at a first time point, and apply a read pass voltage having a second level different from the first level to the first memory cell block at a second time point different from the first time point.

7. The non-volatile memory device of claim 6, wherein
the second time point is after the first time point, and the second level is greater than the first level.

8. The non-volatile memory device of claim 1, wherein
the address decoder is configured to apply a read pass voltage having a first level to a plurality of unselected word lines among a plurality of word lines connected to one memory cell block among the plurality of memory cell blocks, and apply a read pass voltage having a second level that is different from the first level to another one or more unselected word lines.

9. The non-volatile memory device of claim 8, wherein the memory cell array comprises:
a base structure;
a first gate stack disposed on the base structure and comprising a plurality of first gate electrodes, a plurality of first insulating layers, and a first channel hole, wherein the plurality of first gate electrodes and the plurality of first insulating layers are alternately disposed;
a second gate stack disposed on the first gate stack and comprising a plurality of second gate electrodes, a plurality of second insulating layers, and second channel holes, wherein the plurality of second gate electrodes and the plurality of second insulating layers are alternately disposed; and
a plurality of channel structures located inside the first channel hole and the second channel hole and having a shape protruding outward from a boundary between the first channel hole and the second channel hole,
wherein the plurality of unselected word lines correspond to the plurality of first gate electrodes, and the another one or more unselected word lines correspond to the plurality of second gate electrodes.

10. A storage device, comprising:
a non-volatile memory device comprising a memory cell block; and
a storage controller configured to
check a retention level of the memory cell block,
determine a read pass voltage based on the retention level, and
control the non-volatile memory device to apply the read pass voltage to the memory cell block.

11. The storage device of claim 10, wherein
the storage controller is configured to perform an off-cell count operation on the memory cell block and check the retention level based on the off-cell count value.

12. The storage device of claim 11, wherein the storage controller is configured to determine the read pass voltage such that:
the greater the off-cell count value, the lower the read pass voltage is applied, and
the higher the retention level, the lower the read pass voltage is applied.

13. The storage device of claim 10, wherein
the storage controller is configured to check the retention level of the memory cell block after applying power to the non-volatile memory device.

14. The storage device of claim 10, wherein
the storage controller is configured to check a retention level of the memory cell block after performing a program operation on the memory cell block.

15. The storage device of claim 14, wherein
the storage controller is configured to count a time period from performing a program operation on the memory cell block, and check a retention level of the memory cell block based on the time period.

16. The storage device of claim 10, comprising:
a temperature sensor configured to measure the internal temperature of the non-volatile memory device,
wherein the storage controller is configured to
determine a time period based on the temperature, and
when the time period elapses, check a retention level of the memory cell block.

17. An operating method of a storage device, comprising:
checking a retention level of a memory cell block included in a non-volatile memory device;
determining a level of a read pass voltage applied to the memory cell block based on the retention level; and
transmitting a command for controlling the level of the read pass voltage to the determined level to the non-volatile memory device.

18. The operating method of claim 17, wherein checking the retention level of a memory cell block includes:
performing an off-cell count operation on the memory cell block; and
checking the retention level of the memory cell block based on the off-cell count value.

19. The operating method of claim 18, wherein determining the level of the read pass voltage applied to the memory cell block comprises determining the level of the read pass voltage such that:
the greater the off-cell count value, the lower the read pass voltage; and
the higher the retention level, the lower the read pass voltage.

20. The operating method of claim 17, comprising:
measuring the internal temperature of the non-volatile memory device;
determining a time period based on the temperature; and
checking the retention level of the memory cell block after the time period.
